(19) United States
(12) Patent Application Publication
(10) Pub. No.: US 2026/0332158 A1
(43) Pub. Date: Oct. 22, 2026

(54) CURRENT-TIME DOMAIN PROCESSING FOR MULTIPLY OPERATIONS

(71) Applicant: Koushik Krishnan, Saratoga, CA (US)

(72) Inventor: Koushik Krishnan, Saratoga, CA (US)

(21) Appl. No.: 19/455,902

(22) Filed: Jan. 22, 2026

Related U.S. Application Data
(60) Provisional application No. 63/791,110, filed on Apr. 18, 2025.
(60) Provisional application No. 63/819,003, filed on Jun. 6, 2025.

(51) Int. Cl. H03M 1/74; G06J 1/00; H03K 3/017

(52) U.S. Cl. CPC H03M 1/745; G06J 1/00; H03K 3/017

(57) ABSTRACT

Current-Time domain processing for multiply operations is provided. A multiplier circuit comprises a signal generation unit configured to generate at least one control signal based on a first control input and a current generation unit configured to generate current pulses based on a second control input, wherein the first and second control inputs represent components of first and second digital operands. The multiplier circuit further comprises a switching unit operatively coupled to the current generation unit and an integrator unit coupled to an output node of the switching unit. The switching unit selectively controls, based on the control signal, flow of current pulses towards the integrator unit to generate an output signal representing a multiplication result between the first and second digital operands.

### CROSS-REFERENCE TO RELATED APPLICATIONS/INCORPORATION BY REFERENCE

This application claims priority to U.S. Provisional Patent Application Ser. No. 63/791,110 filed on Apr. 18, 2025, and U.S. Provisional Patent Application Ser. No. 63/819,003 filed on Jun. 6, 2025, the entire content of which is hereby incorporated herein by reference.

### TECHNICAL FIELD

The disclosure relates to signal processing systems and more particularly, to methods and systems for performing arithmetic operations using hybrid analog-digital processing techniques.

### BACKGROUND

Digital computing systems rely heavily on arithmetic operations, particularly multiplication and multiply-accumulate functions, which form the foundation of numerous computational tasks. These operations are extensively used in applications such as digital signal processing, machine learning, neural network computations, and scientific computing. As computational demands continue to grow, there has been increasing interest in developing more efficient approaches to perform these fundamental arithmetic operations.

Traditional digital arithmetic implementations typically separate processing units from memory units, which can create data transfer bottlenecks and limit overall system performance. This separation often results in increased latency and power consumption, particularly for data-intensive applications that require frequent memory access. As transistor scaling continues to slow and power efficiency becomes increasingly important, conventional approaches to simply increasing clock speeds or adding more processing cores may not provide proportional performance improvements.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In various embodiments of the disclosure, a multiplier circuit is described. The multiplier circuit includes a signal generation unit configured to generate at least one control signal based on a first control input. The multiplier circuit further includes a current generation unit configured to generate a plurality of current pulses based on a second control input. Each of the first control input and the second control input represents at least one component of a first digital operand or a second digital operand. The multiplier circuit also includes a switching unit operatively coupled to the current generation unit. Additionally, the multiplier circuit includes an integrator unit coupled with an output node of the switching unit. The switching unit is configured to selectively control, based on the at least one control signal, a flow of the plurality of current pulses towards the integrator unit to generate a first output signal at the integrator unit, and the first output signal represents a result of a multiplication operation between the first digital operand and the second digital operand.

According to another aspect of the present disclosure, a method for performing a multiplication operation is described. The method includes generating at least one control signal based on a first control input. The method further includes generating an output current through a current generation unit based on a second control input. Each of the first control input and the second control input represent at least one component of a first digital operand or a second digital operand. The method also includes selectively controlling, based on the at least one control signal, a flow of the output current towards an integrator unit to generate a first output signal at the integrator unit. The first output signal represents a result of the multiplication operation between the first digital operand and the second digital operand.

According to another aspect of the present disclosure, an analog multiplication system is described. The analog multiplication system comprises a memory unit configured to store at least one of a first digital operand and a second digital operand, and a multiplier circuit comprising a signal generation unit configured to generate at least one control signal based on a first control input, a current generation unit configured to generate a plurality of current pulses based on a second control input, a switching unit operatively coupled to the current generation unit, and an integrator unit coupled to an output node of the switching unit. Each of the first control input and the second control input represents at least one component of the first digital operand or the second digital operand. Output lines from the memory unit are operatively coupled to at least one of the current generation unit and the signal generation unit. The switching unit is configured to selectively control, based on the at least one control signal, a flow of the plurality of current pulses towards the integrator unit to generate a first output signal at the integrator unit. The first output signal represents a result of a multiplication operation between the first digital operand and the second digital operand.

The foregoing general description of the illustrative embodiments and the following detailed description thereof are merely exemplary aspects of the teachings of this disclosure and are not restrictive.

Additional technical features and benefits are realized through the techniques of the disclosure. Embodiments and aspects of the disclosure are described in detail herein and are considered a part of the claimed subject matter. For a better understanding, refer to the detailed description and the drawings.

### BRIEF DESCRIPTION OF THE DRAWINGS

The following description will provide details of preferred embodiments with reference to the following figures, wherein:

FIG. 1 is a block diagram that illustrates a multiplier circuit configured to perform multiplication operations using current-time domain processing, in accordance with an embodiment of the disclosure;

FIG. 2 is a circuit diagram that illustrates a modulated current element with a binary-weighted current DAC and single switching element for combined current output, in accordance with an embodiment of the disclosure;

FIG. 3 is a block diagram that illustrates a modulated current element configured for performing multiplication operations using a parallel switching architecture, in accordance with an embodiment of the disclosure;

FIG. 4 is a circuit diagram that illustrates a modulated current element with memory-integrated current sources and bias voltage generation, in accordance with an embodiment of the disclosure;

FIG. 5 is a block diagram that illustrates a modulated current element with multiple current DAC circuits, in accordance with an embodiment of the disclosure;

FIG. 6 is a block diagram that illustrates a modulated current element with hierarchical current DAC organization, in accordance with an embodiment of the disclosure;

FIG. 7 is a circuit diagram that illustrates a multiplier circuit with grouped current sources using differential biasing for area reduction, in accordance with an embodiment of the disclosure;

FIG. 8 is a circuit diagram that illustrates a multiplier circuit with complementary switch pairs for differential output generation, in accordance with an embodiment of the disclosure;

FIG. 9 is a flowchart that illustrates a method for performing a multiplication operation using current-time domain processing, in accordance with an embodiment of the disclosure;

FIG. 10 is a block diagram that illustrates a circuit generation workflow for implementing multiplication operations using current-time domain processing, in accordance with an embodiment of the disclosure;

FIG. 11 is a block diagram that illustrates an analog multiplication system with memory units and processing components, in accordance with an embodiment of the disclosure;

FIG. 12 is a block diagram that illustrates an analog multiplication system with multiple modulated current elements and processing components, in accordance with an embodiment of the disclosure;

FIG. 13 is a block diagram that illustrates an analog multiplication system with distributed memory-processing element pairs, in accordance with an embodiment of the disclosure;

FIG. 14 is a block diagram that illustrates an inference system with ML accelerator for machine learning inference operations, in accordance with an embodiment of the disclosure; and

FIG. 15 is a block diagram that illustrates a training system with training co-processor for machine learning model training operations, in accordance with an embodiment of the disclosure.

### DETAILED DESCRIPTION

Digital computing systems have become fundamental components in modern technology, powering applications ranging from consumer electronics to industrial control systems. These systems rely on performing large numbers of arithmetic operations efficiently, particularly multiplication operations that form the core of many computational tasks. However, as computational demands continue to grow, conventional digital architectures face significant challenges in meeting performance and energy efficiency requirements.

Traditional digital systems typically separate processing units from memory units, creating a data transfer bottleneck that can lead to increased latency and power consumption. This separation becomes particularly problematic for data-intensive tasks that require frequent access to stored values, such as the multiplication operations commonly used in machine learning and signal processing applications. The phenomenon, often referred to as the “memory wall” in computer architecture literature, limits the effective speed of operation as data transport rather than processing element speed becomes the constraining factor.

Additionally, conventional digital multiplication units may be power-hungry, exhibiting lower operations per watt ratios compared to alternative approaches. As transistor scaling slows and simply increasing clock speeds or adding more processing cores becomes less effective at improving overall system performance, new computational paradigms are being explored to overcome these inherent limitations.

The present disclosure describes a hybrid analog-digital approach that addresses these challenges through current-time domain processing techniques for performing multiplication operations. The approach may convert digital inputs into two distinct signal domains: one digital input may be transformed into a control signal such as a pulse width modulated signal where the pulse duration corresponds to the digital value, while another digital input may be implemented through current sources that generate currents proportional to the digital value. These signals may be combined through controlled switching and integrated across a capacitor-based circuit or an active circuit (e.g., an operational amplifier-based integrator) to produce analog output signals representing multiplication results. Multiple multiplication operations can be extended to implement multiply-accumulate (MAC) operations through accumulation of individual multiplication results.

The disclosure introduces several distinct architectural approaches to implement current-time domain processing, each offering specific advantages for different application requirements. A first approach utilizes a binary-weighted current DAC with a single switching element, where current sources are combined at a shorted node and controlled by a single PWM signal. This configuration provides simplicity and minimal switching overhead while maintaining high precision through binary weighting. A second approach employs parallel switching architecture with multiple switches controlling individual current sources, enabling independent control of each bit position. A third approach implements multiple current DAC circuits with place value control, allowing for flexible operand decomposition. Additional architectural variations include grouped current sources with differential biasing, which dramatically reduces area requirements by using independent bias voltages for each current source group rather than replicating unit elements. This approach may reduce transistor count significantly for multi-bit implementations, providing substantial area savings at the cost of some matching accuracy. The disclosure also presents differential output generation through complementary switching, where switch pairs generate both positive and negative signal components, improving noise immunity and dynamic range while enabling direct differential ADC interfacing.

The current-time domain processing method may offer several advantages over existing digital and analog approaches. In terms of operational speed, the system may achieve higher frequencies in advanced technology nodes, representing a significant improvement over traditional digital methods that may be limited by critical path constraints. The speed advantage may arise from the time-domain processing approach, which can be scaled with advances in semiconductor technology nodes as pulse width generation benefits from faster transistor switching in advanced processes.

Power efficiency may be substantially improved compared to conventional digital implementations. The approach may provide significantly better efficiency than traditional digital multiplication units, measured in operations per watt. This improvement may result from performing multiplication operations in the analog domain while maintaining the robustness and precision characteristics of digital systems through the use of digital inputs and outputs.

Area efficiency may also be enhanced, with the approach potentially requiring substantially smaller area overhead compared to digital in-memory compute or near-memory compute implementations. This reduction in area requirements may translate to significantly higher computational density, allowing for more compact and efficient chip designs that can accommodate more processing elements within the same silicon area.

The system may support multiple precision implementations to accommodate different application requirements. The approach may be configured for 4-bit, 8-bit, and 16-bit operations, allowing designers to optimize the trade-off between precision, speed, and power consumption based on specific computational needs. Higher precision implementations may require longer pulse widths, which can affect operational speed, while lower precision implementations may enable faster operation with reduced accuracy.

The scalability of the approach with technology nodes may provide continued performance improvements as semiconductor manufacturing processes evolve. Unlike some analog approaches that may not benefit from technology scaling, the current-time domain processing method may leverage advances in digital circuit performance, particularly in pulse width modulation generation and switching speeds.

The versatility of the approach may enable deployment across diverse application domains. The system may be targeted for accelerator or primary processor applications where high-speed multiplication operations are required. The approach may be suitable for both training and inference applications in machine learning systems, supporting the computational demands of neural network processing where multiplication operations can be extended to multiply-accumulate functions. The method may be implemented in wireless or wireline interface mediums where signal processing operations are performed.

Memory integration capabilities may enable the approach to be deployed in memory chips with in-memory or near-memory processing devices, bringing computation closer to data storage to reduce data movement overhead. The system may also be implemented in processing chips with on-chip memory for storage of vectorized datasets, enabling efficient processing of large data arrays. The approach may be suitable for both edge computing applications where power efficiency and compact implementation are priorities, as well as datacenter applications where high computational throughput and energy efficiency are desired.

The hybrid nature of the approach may combine the speed and scalability advantages of digital processing with the power efficiency benefits of analog computation. By performing multiplication in the analog domain while maintaining digital interfaces, the system may overcome limitations of purely digital or purely analog implementations, providing a balanced solution for high-performance arithmetic operations in modern computing systems.

In various embodiments of the disclosure, a multiplier circuit is described. The multiplier circuit comprises a signal generation unit configured to generate at least one control signal based on a first control input, a current generation unit configured to generate a plurality of current pulses based on a second control input, a switching unit operatively coupled to the current generation unit, and an integrator unit coupled to an output node of the switching unit. Each of the first control input and the second control input represents at least one component of a first digital operand or a second digital operand. The switching unit is configured to selectively control, based on the at least one control signal, a flow of the plurality of current pulses towards the integrator unit to generate a first output signal at the integrator unit. The first output signal represents a result of a multiplication operation between the first digital operand and the second digital operand. This embodiment provides advantages including improved power efficiency through analog domain processing, reduced data movement between memory and processing units, and scalable performance with technology node advances.

In various embodiments of the disclosure, the current generation unit comprises a current Digital-to-Analog (DAC) circuit. The current DAC circuit comprises a plurality of binary-weighted current sources and a plurality of internal switches respectively coupled to the plurality of binary-weighted current sources. An application of the second control input to the plurality of internal switches selectively activates the plurality of binary-weighted current sources to generate the plurality of current pulses. This embodiment provides advantages including precise binary-weighted current generation, efficient bit-level control of current sources, and simplified digital interface for operand representation.

In various embodiments of the disclosure, the first digital operand includes a first digit component and a unit place value component corresponding to the first digit component. The second digital operand includes a second digit component and a unit place value component corresponding to the second digit component. This embodiment provides advantages including simplified operand representation, reduced complexity in control signal generation, and straightforward implementation for basic multiplication operations.

In various embodiments of the disclosure, the switching unit includes a switch coupled to a shorted node of the current DAC circuit. The plurality of current pulses are combined at the shorted node of the current DAC circuit to generate an output current. The at least one component for the first control input includes the first digit component. The at least one control signal includes a Pulse Width Modulated (PWM) signal with a pulse duration that corresponds to a value of the first digit component. The switching unit is configured to control the flow of the output current over the pulse duration to generate the first output signal. This embodiment provides advantages including minimal switching overhead with a single control switch, simplified PWM signal generation, and efficient current combining at the shorted node for reduced circuit complexity.

In various embodiments of the disclosure, the switching unit includes a plurality of switches coupled to the plurality of internal switches of the current DAC circuit. The at least one component for the first control input includes the first digit component. The at least one control signal includes a plurality of Pulse Width Modulated (PWM) signals. Each PWM signal of the plurality of PWM signals is associated with a pulse duration that corresponds to a value of the first digit component. The switching unit is configured to control the flow of the plurality of current pulses current over the pulse duration to generate the first output signal. This embodiment provides advantages including independent control of each current source, parallel processing capability for higher speed operation, and flexible timing control for each bit position.

In various embodiments of the disclosure, the at least one component for the second control input includes the second digit component. The second control input includes a set of bit values that represent the second digit component. The set of bit values acts as a respective set of control signals for the plurality of internal switches. This embodiment provides advantages including direct digital control interface, simplified memory interface for storing operand bits, and efficient bit-level activation of current sources.

In various embodiments of the disclosure, the first digital operand includes a first digit component and a unit place value component corresponding to the first digit component. The second digital operand includes a second digit component as a set of bit values and a second place value component as a set of place values corresponding to the set of bit values. This embodiment provides advantages including flexible operand decomposition, support for different precision requirements, and optimized hardware utilization based on specific application needs.

In various embodiments of the disclosure, the current generation unit comprises a plurality of current Digital-to-Analog (DAC) circuits. Each current DAC circuit of the plurality of current DAC circuits comprises a current source and an internal switch coupled to the current source. This embodiment provides advantages including modular current generation architecture, scalable design for different bit widths, and simplified individual current source control.

In various embodiments of the disclosure, the switching unit includes a plurality of switches. Each switch of the plurality of switches is coupled to the internal switch of a respective current DAC circuit of the plurality of current DAC circuits. The at least one component for the first control input includes the first digit component and the second place value component. The at least one control signal includes a plurality of Pulse Width Modulated (PWM) signals. Each PWM signal of the plurality of PWM signals is associated with a respective pulse duration that is proportional to a product of a value of the first digit component and a respective place value of the set of place values. The switching unit is configured to control the flow of each current pulse of the plurality of current pulses over the respective pulse duration to generate the first output signal. This embodiment provides advantages including place value weighting in the time domain, independent control of each bit position, and efficient multiplication through combined digit and place value processing.

In various embodiments of the disclosure, the at least one component for the second control input includes the second digit component. The second control input includes the set of bit values that represent the second digit component. Each binary value of the set of binary values acts as a respective control signal for the internal switch of a respective current DAC circuit of the plurality of current DAC circuits. An application of each binary value of the set of bit values to the internal switch of the respective current DAC circuit selectively activates the current source in the respective current DAC circuit of the plurality of current DAC circuits to generate a respective current pulse of the plurality of current pulses. This embodiment provides advantages including direct bit-to-current mapping, simplified control logic for current source activation, and efficient parallel processing of multiple bit positions.

In various embodiments of the disclosure, the first digital operand includes a first digit component as a set of bit values and a second place value component as a set of place values corresponding to the set of bit values. The second digital operand includes a second digit component and a unit place value component corresponding to the second digit component. This embodiment provides advantages including flexible bit-level decomposition of the first operand, support for arbitrary place value assignments, and optimized hardware allocation based on operand characteristics.

In various embodiments of the disclosure, the switching unit includes a set of switches corresponding to the set of bit values. The at least one component for the first control input includes the first digit component. This embodiment provides advantages including one-to-one correspondence between bits and switches, simplified control signal distribution, and efficient bit-level switching control.

In various embodiments of the disclosure, the current generation unit comprises a plurality of current Digital-to-Analog (DAC) circuits in a specific configuration. The specific configuration includes a specific set of current DAC circuits of the plurality of current DAC circuits for each switch of the set of switches. A number of current DAC circuits in the specific set of current DAC circuits corresponds to a respective place value of the set of place values. This embodiment provides advantages including hardware allocation proportional to place values, optimized area utilization for different bit weights, and scalable architecture for various precision requirements.

In various embodiments of the disclosure, each current DAC circuit of the plurality of current DAC circuits comprises a plurality of binary-weighted current sources and a plurality of internal switches respectively coupled to the plurality of binary-weighted current sources. The at least one component for the second control input includes the second digit component. The second control input includes a set of bit values representing the second digit component. An application of the set of bit values to the plurality of binary-weighted current sources selectively activates the plurality of binary-weighted current sources in each current DAC circuit of the plurality of current DAC circuits to generate a respective current pulse of the plurality of current pulses. This embodiment provides advantages including hierarchical current generation with binary weighting, efficient reuse of control signals across multiple DAC circuits, and scalable precision through modular DAC architecture.

In various embodiments of the disclosure, each switch of the set of switches is coupled to a shorted output of the specific set of current DAC circuits. The at least one component for the first control input includes the first digit component. The at least one control signal includes a plurality of Pulse Width Modulated (PWM) signals. Each PWM signal of the plurality of PWM signals is associated with a respective pulse duration that is proportional to a respective bit value of the set of bit values. The switching unit is configured to control the flow of each current pulse of the plurality of current pulses over the respective pulse duration to generate the first output signal. This embodiment provides advantages including efficient current combining through shorted outputs, bit-proportional timing control, and simplified integration of multiple current sources.

In various embodiments of the disclosure, the at least one control signal is a Pulse Width Modulated (PWM) signal and the signal generation unit includes a Digital-to-Time (DTC) converter. This embodiment provides advantages including precise time-domain signal generation, scalability with technology node advances, and efficient conversion from digital values to time-domain representation.

In various embodiments of the disclosure, the first output signal is a voltage signal that is generated based on a charge accumulation on the integrator unit over a pulse duration of the at least one control signal. The charge accumulation is caused by the controlled flow of the plurality of current pulses towards the integrator unit. This embodiment provides advantages including natural integration of current over time, voltage output suitable for ADC conversion, and inherent multiplication through charge accumulation.

In various embodiments of the disclosure, the current generation unit includes a current Digital-to-Analog Converter (DAC) circuit comprising at least one current source. The at least one current source comprises a set of transistors in a parallel configuration. Each transistor of the set of transistors includes a gate terminal coupled to a common bias voltage. This embodiment provides advantages including good current matching through common bias voltage, scalable current levels through parallel transistor configuration, and simplified bias generation circuitry.

In various embodiments of the disclosure, the current generation unit includes a current Digital-to-Analog Converter (DAC) circuit. The current DAC circuit comprises a plurality of current sources in a plurality of groups. Each current source of the plurality of current sources is a binary-weighted current source that corresponds to a respective place value of a respective bit of one of the first digital operand or the second digital operand. Each group of the plurality of groups includes at least one current source of the plurality of current sources. The at least one current source in each group of the plurality of groups includes a specific transistor-based circuit that is biased with a different bias voltage. The different bias voltage for each group of the plurality of groups is such that a current output of each current source of the at least one current source in a respective group of the plurality of groups is proportional to the respective place value corresponding to a respective current source of the plurality of current sources. This embodiment provides advantages including dramatic area reduction compared to unit element replication, independent bias control for each current group, and flexible current scaling through bias voltage adjustment.

In various embodiments of the disclosure, the integrator unit comprises an integrator circuit with at least one active circuit component. This embodiment provides advantages including active integration for improved performance, enhanced signal conditioning capabilities, and better control over integration characteristics.

In various embodiments of the disclosure, the integrator unit comprises a parallel array of capacitors. Each capacitor of the parallel array of capacitors is between a common ground node and a respective switch of a set of switches of the switching unit. An output across each capacitor of the parallel array of capacitors is shorted. This embodiment provides advantages including parallel charge accumulation, shared output through shorted connections, and distributed capacitive loading for improved speed.

In various embodiments of the disclosure, the integrator unit comprises a common capacitor connected between a shorted output of the switching unit and a common ground node. This embodiment provides advantages including simplified capacitor implementation, centralized charge accumulation, and reduced component count for compact design.

In various embodiments of the disclosure, the current generation unit comprises a plurality of current sources and a plurality of internal switches respectively coupled to the plurality of current sources. The switching unit comprises a plurality of switch pairs. An input to each switch pair of the plurality of switch pairs is coupled to a respective internal switch of the plurality of internal switches. The at least one control signal includes a respective pair of complementary signals for each switch pair of the plurality of switch pairs. Each switch pair of the plurality of switch pairs comprises a first switch for a first signal of the respective pair of complementary signals and a second switch for a second signal of the respective pair of complementary signals. The integrator unit comprises a pair of capacitors. Outputs of the first switch from each switch pair of the plurality of switch pairs is shorted and coupled to a first capacitor of the pair of capacitors. Outputs of the second switch from each switch pair of the plurality of switch pairs is shorted and coupled to a second capacitor of the pair of capacitors. An application of the respective pair of complementary signals to each switch pair of the plurality of switch pairs selectively controls the flow of the plurality of current pulses towards the pair of capacitors to generate the first output signal at the first capacitor and a second output signal at the second capacitor. The second output signal is different from the first output signal. This embodiment provides advantages including differential signal generation for improved noise immunity, doubled dynamic range for ADC input, and complementary signal processing for enhanced accuracy.

In various embodiments of the disclosure, the multiplier circuit further comprises a signal processing unit configured to generate a third output signal based on the first output signal and the second output signal. The third output signal represents the result of the multiplication operation between the first digital operand and the second digital operand. This embodiment provides advantages including differential signal processing for improved accuracy, noise cancellation through signal subtraction, and enhanced dynamic range in the final output.

In various embodiments of the disclosure, the multiplier circuit further comprises a memory array configured to store the second digital operand. Output lines from the memory array are operatively coupled to the current generation unit. This embodiment provides advantages including in-memory computing capability, reduced data movement between memory and processing units, and efficient operand storage and retrieval.

In various embodiments of the disclosure, the multiplier circuit is co-located on a semiconductor die or within a chip package that includes the memory array or embedded within a physical layout of the memory array. This embodiment provides advantages including minimized interconnect delays, reduced power consumption through proximity, and compact system integration for improved performance.

In various embodiments of the disclosure, the multiplier circuit further comprises an analog-to-digital converter configured to convert the first output signal to a digital output representing the result in a digital form. This embodiment provides advantages including digital output compatibility with downstream processing, quantized result representation for storage and transmission, and interface compatibility with digital systems.

In various embodiments of the disclosure, the multiplier circuit further comprises a reset switch operatively coupled to the integrator unit. The reset switch is configured to reset the first output signal to an initial value before the multiplication operation. This embodiment provides advantages including controlled initialization of integration, prevention of charge accumulation from previous operations, and reliable operation across multiple multiplication cycles.

In various embodiments of the disclosure, a method for performing a multiplication operation is described. The method comprises generating at least one control signal based on a first control input, generating an output current through a current generation unit based on a second control input, and selectively controlling, based on the at least one control signal, a flow of the output current towards an integrator unit to generate a first output signal at the integrator unit. Each of the first control input and the second control input represent at least one component of a first digital operand or a second digital operand. The first output signal represents a result of the multiplication operation between the first digital operand and the second digital operand. This embodiment provides advantages including efficient analog domain multiplication, reduced computational complexity compared to digital methods, and scalable performance with technology advances.

In various embodiments of the disclosure, an analog multiplication system is described. The analog multiplication system comprises a memory unit configured to store at least one of a first digital operand and a second digital operand, and a multiplier circuit comprising a signal generation unit configured to generate at least one control signal based on a first control input, a current generation unit configured to generate a plurality of current pulses based on a second control input, a switching unit operatively coupled to the current generation unit, and an integrator unit coupled to an output node of the switching unit. Output lines from the memory unit are operatively coupled to at least one of the current generation unit and the signal generator unit. Each of the first control input and the second control input represents at least one component of the first digital operand or the second digital operand. The switching unit is configured to selectively control, based on the at least one control signal, a flow of the plurality of current pulses towards the integrator unit to generate a first output signal at the integrator unit. The first output signal represents a result of a multiplication operation between the first digital operand and the second digital operand. This embodiment provides advantages including integrated memory and processing architecture, reduced data transfer overhead, and efficient system-level implementation for multiply-accumulate operations.

The following description sets forth exemplary aspects of the present disclosure. It should be recognized, however, that such description is not intended as a limitation on the scope of the present disclosure. Rather, the description also encompasses combinations and modifications to those exemplary aspects described herein.

A detailed description of systems, devices, and methods consistent with embodiments of the present disclosure is provided below. While several embodiments are described, it should be understood that disclosure is not limited to any one embodiment, but instead encompasses numerous alternatives, modifications, and equivalents. In addition, while numerous specific details are set forth in the following description in order to provide a thorough understanding of the embodiments disclosed herein, some embodiments can be practiced without some or all of these details. Moreover, for the purpose of clarity, certain technical material that is known in the related art has not been described in detail in order to avoid unnecessarily obscuring the disclosure.

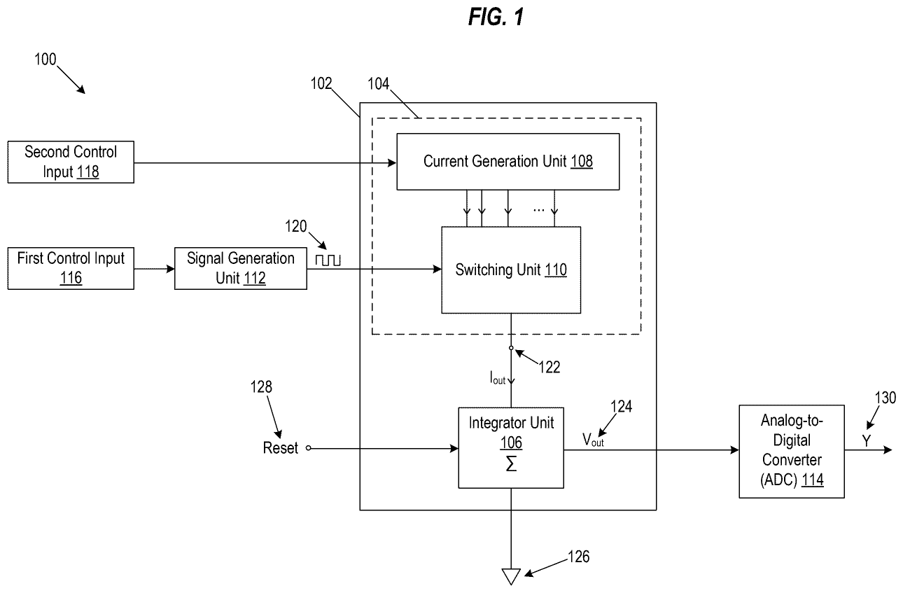

FIG. 1 is a block diagram 100 that illustrates a multiplier circuit 102 configured to perform multiplication operations using current-time domain processing, in accordance with an embodiment of the disclosure. The multiplier circuit 102 includes a modulated current element (MCE) 104 and an integrator unit 106. The modulated current element (MCE) 104 comprises a current generation unit 108, a switching unit 110, and a signal generation unit 112. The integrator unit 106 is coupled to an output node 122 of the switching unit 110 and is configured to generate a first output signal 124 that represents a result of a multiplication operation between digital operands.

The signal generation unit 112 is configured to receive a first control input 116 and generate at least one control signal 120 based on the first control input 116. The signal generation unit 112 may implement pulse width modulation for time-domain signal generation, where the at least one control signal 120 is a Pulse Width Modulated (PWM) signal. The PWM signal has a pulse duration that is proportional to a value represented by the first control input 116. In some cases, the signal generation unit 112 includes a Digital-to-Time (DTC) converter for precise conversion from digital values to time-domain representation. The signal generation unit 112 may be implemented using various architectures, including digital-to-time converters (DTCs), delay-line based circuits, counter-based PWM generators that utilize master clock references, voltage-controlled oscillator (VCO) based timing circuits, voltage-controlled delay lines, phase-locked loop (PLL) based timing generators, or ring oscillator-based timing circuits. The PWM signal generation provides scalability with technology node advances and efficient time-domain signal generation. The PWM signal generation may support multiple precision implementations, where 4-bit operands may generate pulse widths from 0 to 15 time units, 8-bit operands may generate pulse widths from 0 to 255 time units, and 16-bit operands may generate pulse widths from 0 to 65535 time units, enabling flexible precision-speed trade-offs based on application requirements.

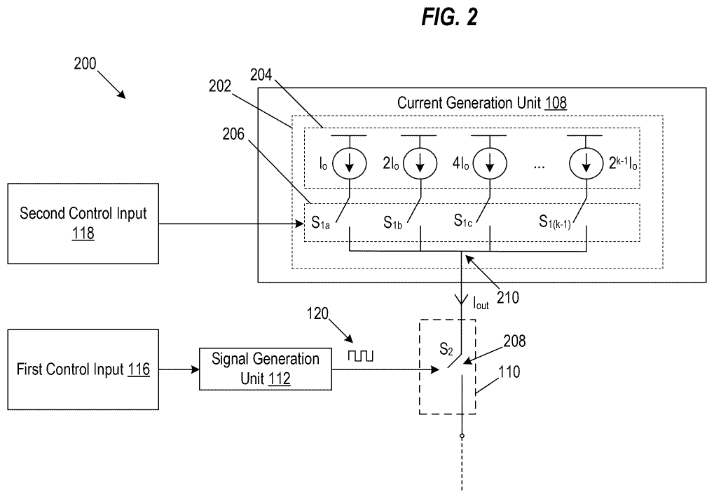

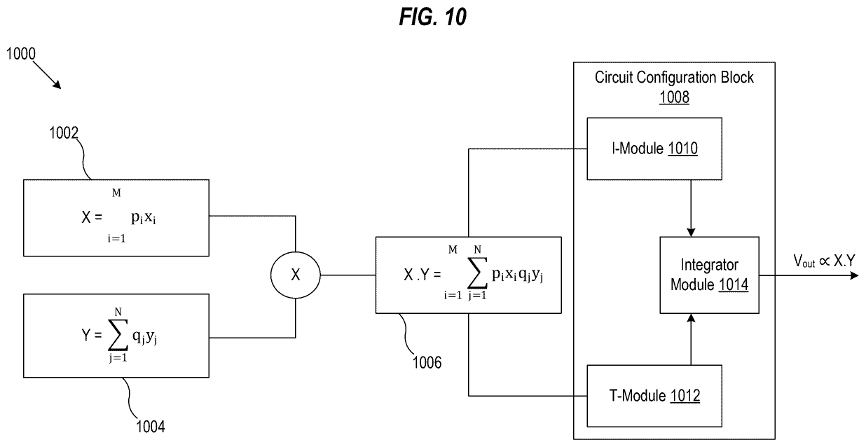

The current generation unit 108 is configured to receive a second control input 118 and generate a plurality of current pulses based on the second control input 118. The current generation unit 108 may be implemented using different current source topologies, such as transistor-based current mirrors, cascode current source configurations, resistor-ladder networks, or switched-capacitor current sources. Each of the first control input 116 and the second control input 118 represents at least one component of a first digital operand or a second digital operand through operand decomposition techniques. The digital operands may be decomposed into digit components and corresponding place value components, where digit components represent individual digit values and place value components represent the positional weights associated with each digit. This decomposition enables flexible representation of digital operands, where the first control input 116 and second control input 118 may represent different combinations of digit and place value components depending on the specific implementation. The digit-place value representations are used to configure the control inputs and determine the configuration of current sources within the current generation unit 108, enabling various architectural approaches as illustrated in FIGS. 2-6. FIG. 10 demonstrates the systematic approach to arrive at the variations through modular operand decomposition, where different combinations of digit and place value assignments lead to distinct circuit configurations while maintaining the fundamental multiplication operation through analog domain processing with digital input and output interfaces for compatibility with conventional digital systems.

The switching unit 110 is operatively coupled to the current generation unit 108 and configured to receive the at least one control signal 120 from the signal generation unit 112. The switching unit 110 may comprise various switch implementations, including MOSFET switches, transmission gates, analog multiplexers, or current steering circuits, with control signals routed through dedicated control lines, bus structures, or differential signal pairs. The output node 122 of the switching unit 110 is coupled to the integrator unit 106. The switching unit 110 is configured to selectively control, based on the at least one control signal 120, a flow of the plurality of current pulses towards the integrator unit 106 to generate the first output signal 124 at the integrator unit 106. The switching unit 110 implements a logical AND operation between the at least one control signal 120 and control signals from the current generation unit 108, ensuring that current flows to the integrator unit 106 only during specific time intervals determined by the at least one control signal 120 and when corresponding control conditions are satisfied. The first output signal 124 represents a result of a multiplication operation between the first digital operand and the second digital operand.

As shown in FIG. 1, the integrator unit 106 is connected between the output node 122 and a ground node 126. The ground node 126 may be implemented as a dedicated ground plane, substrate connection, or common reference node shared across multiple circuit blocks to provide a stable reference potential for voltage measurements and current return paths. The integrator unit 106 generates the first output signal 124 based on charge accumulation resulting from the controlled flow of the plurality of current pulses. The integrator unit 106 may be implemented using various capacitive structures, including metal-insulator-metal (MIM) capacitors, metal-oxide-semiconductor (MOS) capacitors, parasitic capacitance within a circuit layout of the multiplier circuit 102, or active integrator circuits with operational amplifiers. The first output signal 124 is a voltage signal that is generated based on a charge accumulation on the integrator unit 106 over a pulse duration of the at least one control signal 120, and the charge accumulation is caused by the controlled flow of the plurality of current pulses towards the integrator unit 106. The mathematical relationship for this operation may be expressed as Vₒᵤₜ=(I×T)/C, where I represents the current magnitude determined by the second control input, T represents the pulse duration determined by the first control input, and C represents the capacitance value of the integrator unit 106. The charge accumulation process may follow the relationship Q=∫I dt, where the integral represents the accumulation of current over time during the pulse duration, effectively performing analog multiplication through time-domain integration of current pulses.

The integrator unit 106 may be implemented using various configurations to optimize performance characteristics for different application requirements. In some cases, the integrator unit 106 comprises an integrator circuit with at least one active circuit component, such as operational amplifiers, transconductance amplifiers, or current conveyors, providing active integration for improved performance, enhanced signal conditioning capabilities, and better control over integration characteristics. Alternatively, the integrator unit 106 comprises a parallel array of capacitors, where each capacitor of the parallel array of capacitors is between a common ground node and a respective switch of a set of switches of the switching unit 110, and an output across each capacitor of the parallel array of capacitors is shorted for parallel charge accumulation, distributed capacitive loading for improved speed, and enhanced current handling capability. In other implementations, the integrator unit 106 comprises a common capacitor connected between a shorted output of the switching unit 110 and a common ground node, providing simplified capacitor implementation, centralized charge accumulation, reduced component count for compact design, and straightforward voltage measurement across a single capacitive element. In some implementations, the integrator unit 106 may utilize parasitic capacitance, where the inherent capacitance of the circuit elements, interconnect traces, transistor gate capacitances, or junction capacitances may serve as an integration capacitor. This approach may enable higher operational frequencies by minimizing the capacitive loading, reducing RC time constants that could otherwise limit the speed of operation, and eliminating the need for dedicated large-value capacitors that may consume significant chip area. The parasitic capacitance approach may be particularly beneficial in advanced technology nodes where smaller feature sizes result in reduced parasitic capacitances that enable faster charging and discharging cycles.

The multiplier circuit 102 further comprises a reset switch 128 operatively coupled to the integrator unit 106. The reset switch 128 may be implemented using various switch technologies, including NMOS transistors, PMOS transistors, transmission gates, or analog switches, with control signals provided through dedicated reset control lines, timing circuits, or system clock-derived reset signals. The reset switch 128 is configured to reset the first output signal 124 to an initial value before the multiplication operation by connecting the output node 122 to the ground node 126. The reset switch 128 is connected for capacitor discharge before each multiply operation, enabling the integrator unit 106 to be reset (i.e., Vₒᵤₜ=0 Volts) to a known state prior to subsequent multiplication operations. This reset functionality enables controlled initialization of the integration process, preventing charge accumulation from previous operations and ensuring reliable operation across multiple multiplication cycles, thereby maintaining accuracy and preventing error accumulation in sequential operations.

With continued reference to FIG. 1, the multiplier circuit 102 further comprises an analog-to-digital converter (ADC) 114 coupled to the integrator unit 106 and configured to receive the first output signal 124. The ADC 114 may be implemented using various ADC architectures, including successive approximation register (SAR) ADCs, sigma-delta ADCs, flash ADCs, pipeline ADCs, or dual-slope ADCs, depending on speed, precision, and power consumption requirements. The ADC 114 receives the first output signal 124 from the integrator unit 106 through analog signal routing, which may include shielded signal traces, differential signal pairs, buffered signal paths, or sample-and-hold circuits to minimize noise and interference. The connection between the integrator unit 106 and the ADC 114 may incorporate additional signal conditioning elements such as anti-aliasing filters, programmable gain amplifiers, offset compensation circuits, or scaling factors to counter the effects of capacitance value variations and process tolerances. The ADC 114 is configured to convert the first output signal 124 to a digital output 130 representing the result in a digital form. The digital output of 130 may be provided through various digital interfaces, including parallel data buses, serial communication protocols, memory-mapped registers, or direct connections to downstream digital processing blocks. This conversion provides digital output compatibility with downstream processing systems and enables quantized result representation for storage, transmission, and further digital processing operations.

The operational timing sequence of the multiplier circuit 102 may include multiple phases for controlled operation and reliable multiplication results. The phases may include a reset phase for capacitor discharge, where the reset switch 128 may discharge any accumulated charge on the integrator unit 106 to establish a known initial state, typically lasting for a brief period such as 1 nanosecond or several clock cycles. A PWM phase may follow for signal application, where the at least one control signal 120 may be applied to control the switching unit 110, with the PWM signal duration determined by the value of the first control input 116 and ranging from zero to a maximum pulse width corresponding to the full-scale input value. An integration phase may then occur for current accumulation, where the plurality of current pulses may flow through the switching unit 110 to the integrator unit 106 based on the state of the at least one control signal 120, with current magnitude determined by the second control input 118 through selective activation of current sources. A readout phase may complete the sequence, where the first output signal 124 is measured and converted to the digital output 130 through the ADC 114.

Although not shown in FIG. 1, the multiplier circuit 102 may be integrated with memory systems for enhanced functionality and reduced data movement overhead. The multiplier circuit 102 may include a memory unit configured to store the second digital operand, and output lines from the memory unit may be operatively coupled to the current generation unit 108 through direct connections, shared bus structures, or dedicated data paths. The memory unit may be implemented using various memory technologies, including static random-access memory (SRAM), dynamic random-access memory (DRAM), non-volatile memory such as flash or resistive RAM, or emerging memory technologies. This integration enables in-memory computing capability, reduces data movement between memory and processing units, and improves overall system efficiency by bringing computation closer to data storage. The multiplier circuit 102 is co-located on a semiconductor die or within a chip package that includes the memory array or embedded within a physical layout of the memory array, providing minimized interconnect delays, reduced power consumption through proximity, compact system integration for improved performance, and efficient utilization of chip area through shared infrastructure and optimized layout arrangements.

FIG. 2 is a circuit diagram that illustrates a modulated current element 200 with a binary-weighted current DAC and single switching element for combined current output, in accordance with an embodiment of the disclosure. FIG. 2 is described in conjunction with elements from FIG. 1. The modulated current element 200 comprises the current generation unit 108, the switching unit 110, and the signal generation unit 112, which are interconnected to control the flow of current pulses based on digital operands. The modulated current element 200 implements a binary-weighted current DAC approach where the second digital operand is represented through selective activation of weighted current sources, while the first digital operand is represented through pulse width modulation in the time domain.

The current generation unit 108 comprises a current Digital-to-Analog (DAC) circuit 202. The current DAC circuit 202 comprises a plurality of binary-weighted current sources 204 and a plurality of internal switches 206 respectively coupled to the plurality of binary-weighted current sources 204. The plurality of binary-weighted current sources 204 includes individual current sources labeled as I₀, 2I₀, 4I₀, and 2^{(k-1)}I₀, where each current source is weighted according to binary place values. The binary weighting scheme ensures that each current source contributes a specific weighted value to the total output current, with the weighting following powers of two to match the binary representation of digital operands. The current sources may be implemented using various transistor configurations, including current mirror circuits with scaled transistor sizes, parallel transistor arrangements with common bias voltages, or cascode current source topologies.

Each current source of the plurality of binary-weighted current sources 204 is coupled in series with a corresponding internal switch of the plurality of internal switches 206, labeled as S₁ₐ, S_{1b}, S_{1c}, and S₁₍ₖ₋₁₎ respectively. The plurality of internal switches 206 are controlled by the second control input 118, which provides bit values representing a second digital operand. The second control input 118 is shown with individual bit lines that connect to the respective internal switches S₁ₐ, S_{1b}, S_{1c}, and S₁₍ₖ₋₁₎. When a bit value is high, the corresponding internal switch closes, allowing current to flow from the associated current source. When a bit value is low, the corresponding internal switch opens, blocking current flow from that particular current source. An application of the second control input 118 to the plurality of internal switches 206 selectively activates the plurality of binary-weighted current sources 204 to generate the plurality of current pulses.

The first digital operand includes a first digit component and a unit place value component corresponding to the first digit component, and the second digital operand includes a second digit component and a unit place value component corresponding to the second digit component. The second digital operand may be mathematically represented as W=Σ_{(i=0 to k-1)}wᵢ·2ⁱ, where wᵢ∈{0,1} represents the individual bit values and k represents the bit width of the operand. The at least one component for the second control input 118 includes the second digit component, where the second control input 118 includes a set of bit values that represent the second digit component. The set of bit values acts as a respective set of control signals for the plurality of internal switches 206. Each bit value wᵢ directly controls the corresponding internal switch, creating a one-to-one mapping between the binary representation of the second digital operand and the activation state of the current sources.

As shown in FIG. 2, the outputs of the plurality of internal switches 206 are connected to a shorted node 210, where the individual currents from the activated current sources combine to form an output current Iₒᵤₜ. The shorted node 210 serves as a current summing junction where the binary-weighted currents are combined according to the bit pattern of the second digital operand. The plurality of current pulses are combined at the shorted node 210 of the current DAC circuit 202 to generate an output current. The output current Iₒᵤₜ represents the analog equivalent of the second digital operand, with the magnitude determined by which current sources are activated through their corresponding internal switches. The current combining at the shorted node 210 follows the relationship Iₒᵤₜ=Σ_{(i=0 to k-1)}wᵢ·2ⁱ·I₀, where activated current sources contribute their weighted values to the total output current.

The switching unit 110 includes a switch 208 coupled to a shorted node 210 of the current DAC circuit 202. The switch 208 is positioned between the shorted node 210 and an output terminal. The switch 208 is controlled by the at least one control signal 120, which is generated by the signal generation unit 112 based on the first control input 116. The signal generation unit 112 receives the first control input 116, which represents a first digital operand, and generates the at least one control signal 120 as a Pulse Width Modulated (PWM) signal. The at least one component for the first control input 116 includes the first digit component, and the at least one control signal 120 includes a Pulse Width Modulated (PWM) signal with a pulse duration that corresponds to a value of the first digit component. The pulse duration of the at least one control signal 120 is proportional to the value of the first digital operand, establishing the time-domain representation of the multiplication operand.

The switch 208 selectively controls the flow of the output current Iₒᵤₜ from the shorted node 210 toward the integrator unit (such as the integrator unit 106) based on the state of the at least one control signal 120. When the at least one control signal 120 is high, the switch 208 closes, allowing the output current Iₒᵤₜ to flow toward the integrator unit. When the at least one control signal 120 is low, the switch 208 opens, blocking the current flow. The switching unit 110 is configured to control the flow of the output current over the pulse duration to generate the first output signal 124. This configuration enables the modulated current element 200 to perform multiplication by integrating the output current over the pulse duration determined by the first digital operand, while the magnitude of the output current is determined by the second digital operand through the selective activation of the plurality of binary-weighted current sources 204.

The mathematical relationship for the multiplication operation may be expressed through the integration process, where the first output signal 124 is generated based on charge accumulation. The output voltage at the end of the integration period may be represented as Vₒᵤₜ|_{(t=TX)}=(I₀·X·W)/C, where X represents the value of the first digital operand, W represents the value of the second digital operand, I₀ represents the base current unit, and C represents the capacitance of the integrator unit. The timing relationship may be expressed as T_{N}=N·Tᵤ+Δ, where N=max(X) represents the maximum value of the first operand, Tᵤ represents the unit time interval, and Δ represents a constant offset for timing margins. The integration produces Vₒᵤₜ=(I_{DAC}·T_{X})/C, where T_{X} is proportional to the first operand X and I_{DAC} is proportional to the second operand W, effectively implementing analog multiplication through the combination of time-domain and current-domain signal processing.

It should be noted that the modulated current element 200 shown in FIG. 2 may be connected to an integrator unit and other processing components as described with reference to FIG. 1. The integrator unit may be coupled to the output node of the switching unit to receive the controlled flow of current pulses and generate an output signal representing the multiplication result. The modulated current element configuration shown in FIG. 2 is illustrated in a reduced form for clarity and brevity, with the understanding that the complete multiplier circuit includes the integrator unit, analog-to-digital converter (ADC), and other processing components as described in FIG. 1.

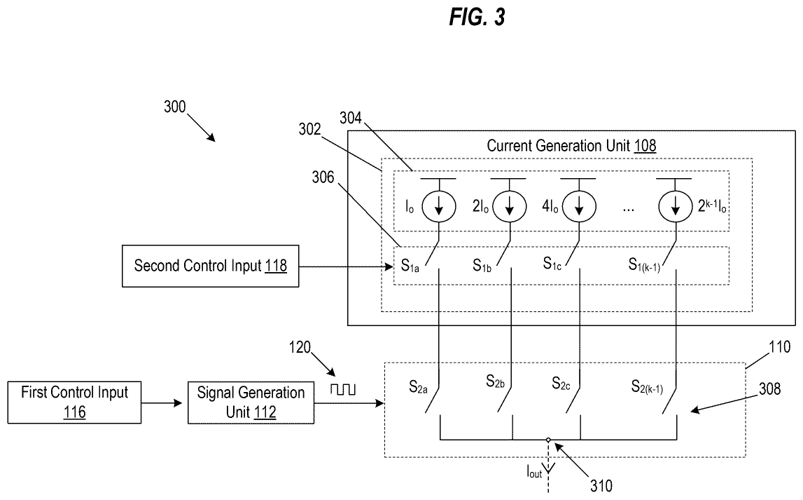

FIG. 3 is a block diagram that illustrates a modulated current element 300 configured for performing multiplication operations using a parallel switching architecture, in accordance with an embodiment of the disclosure. FIG. 3 is described in conjunction with elements from FIG. 1. The modulated current element 300 comprises the current generation unit 108, the switching unit 110, and the signal generation unit 112, which are interconnected to provide independent control of individual current paths through parallel switching elements. The modulated current element 300 implements an alternative approach to the shorted-node configuration shown in FIG. 2, where individual switching elements control each binary-weighted current source separately rather than combining currents at a common node before switching.

The current generation unit 108 includes a current Digital-to-Analog (DAC) circuit 302 configured to receive the second control input 118. The current DAC circuit 302 comprises a plurality of binary-weighted current sources 304 and a plurality of internal switches 306 respectively coupled to the plurality of binary-weighted current sources 304. The plurality of binary-weighted current sources 304 may be implemented using similar binary weighting schemes as described for FIG. 2, with individual current sources generating currents proportional to powers of two (I₀, 2I₀, 4I₀, etc.) to match the binary representation of digital operands. Each current source of the plurality of binary-weighted current sources 304 is coupled in series with a corresponding internal switch of the plurality of internal switches 306, enabling selective activation of individual current sources based on bit values of the second digital operand.

The plurality of binary-weighted current sources 304 are connected to a shorted node 310, where the outputs of the plurality of binary-weighted current sources 304 are combined when their corresponding internal switches are activated. The shorted node 310 serves as a current summing junction similar to the configuration in FIG. 2, but the subsequent switching architecture differs in the parallel switching approach. An application of the second control input 118 to the plurality of internal switches 306 selectively activates the plurality of binary-weighted current sources 304 to generate the plurality of current pulses. The second control input 118 includes a set of bit values that represent the second digit component of the second digital operand, and the set of bit values acts as a respective set of control signals for the plurality of internal switches 306.

The switching unit 110 includes a plurality of switches 308 coupled to the plurality of internal switches 306 of the current DAC circuit 302. The plurality of switches 308 provides individual control over each current path from the plurality of binary-weighted current sources 304, enabling independent switching of each binary-weighted current contribution. The at least one component for the first control input 116 includes the first digit component, and the at least one control signal 120 includes a plurality of Pulse Width Modulated (PWM) signals. Each PWM signal of the plurality of PWM signals is associated with a pulse duration that corresponds to a value of the first digit component. The switching unit 110 is configured to control the flow of the plurality of current pulses over the pulse duration to generate the first output signal 124.

The parallel switching architecture differs from the configuration shown in FIG. 2 by implementing individual control of each current source through the plurality of switches 308, where each PWM signal controls an individual current path rather than controlling a combined current at a single switching point. The plurality of switches 308 are positioned to control the flow of current from each of the plurality of internal switches 306 independently, enabling parallel processing of multiple current paths. Each switch of the plurality of switches 308 receives a respective PWM signal from the plurality of PWM signals, allowing for independent timing control of each binary-weighted current contribution. The switching unit 110 controls flow of the plurality of current pulses in parallel, with each PWM signal having pulse duration corresponding to the first digit component value.

The mathematical representation for this configuration may be expressed as W=Σ(i=0 to k−1)wᵢ·2ⁱ, where wᵢ represents the individual bit values of the second digital operand and k represents the bit width. The PWM signals are generated proportional to X×T_{N}, where X represents the value of the first digital operand and T_{N} represents the normalized time unit. The first digital operand includes a first digit component and a unit place value component corresponding to the first digit component, and the second digital operand includes a second digit component and a unit place value component corresponding to the second digit component. The at least one component for the second control input 118 includes the second digit component, enabling direct control of the plurality of internal switches 306 through the bit values of the second digital operand.

The architecture provides speed that scales with technology node advances, as the individual switching elements may benefit from improved transistor performance in advanced semiconductor processes. However, the parallel switching approach may operate slower than the shorted-node configuration shown in FIG. 2, as the individual control of multiple switching elements may introduce additional propagation delays and timing coordination requirements compared to the single-switch approach.

The parallel switching architecture enables independent control of each binary-weighted current contribution, providing enhanced flexibility in timing control and potentially improved isolation between different bit positions. Each switch of the plurality of switches 308 may be controlled with independent timing, allowing for advanced timing schemes where different bit positions may have slightly different pulse durations or timing offsets to compensate for process variations or optimize performance characteristics. The independent control capability may also enable fault tolerance features, where individual current sources or switches may be disabled or bypassed if defects are detected, while maintaining functionality through the remaining operational elements.

The signal generation unit 112 generates the plurality of PWM signals based on the first control input 116, where each PWM signal may be derived from the same base timing reference but applied to individual switches of the plurality of switches 308. The PWM signal generation may utilize shared timing circuits with multiple output channels, distributed delay elements for individual timing control, or parallel PWM generators that operate synchronously to maintain timing coherence across the multiple current paths. The parallel PWM generation may enable higher precision timing control for each bit position while maintaining overall system synchronization through common clock references or phase-locked timing circuits.

It should be noted that the modulated current element 300 shown in FIG. 3 may be connected to an integrator unit and other processing components as described with reference to FIG. 1. The integrator unit may be coupled to the output node of the switching unit to receive the controlled flow of current pulses and generate an output signal representing the multiplication result. The modulated current element configuration shown in FIG. 3 is illustrated in a reduced form for clarity and brevity, with the understanding that the complete multiplier circuit includes the integrator unit, analog-to-digital converter (ADC), and other processing components as described in FIG. 1.

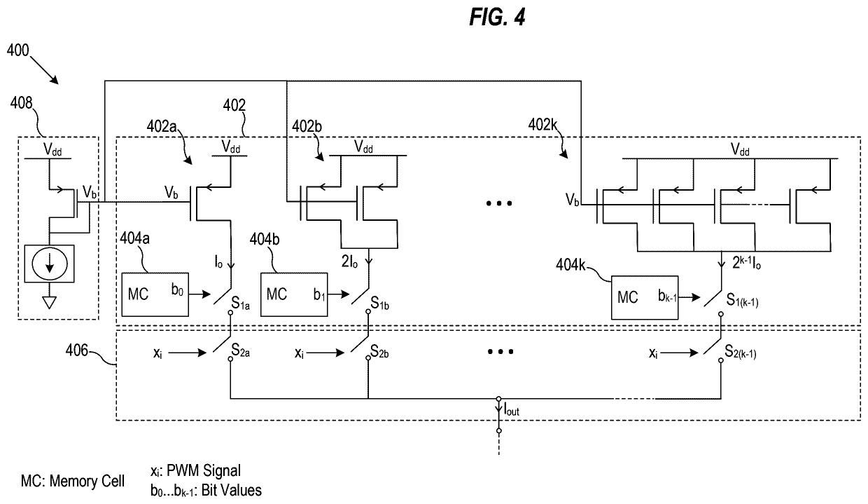

FIG. 4 is a circuit diagram that illustrates a modulated current element 400 with memory-integrated current sources and bias voltage generation, in accordance with an embodiment of the disclosure. FIG. 4 is described in conjunction with elements from FIG. 1. The modulated current element 400 comprises a current Digital-to-Analog Converter (DAC) circuit 402, memory cells for storing digital operand values, a switching unit 406, and a bias voltage generator 408. The modulated current element 400 demonstrates an alternative approach to current generation that utilizes transistor-based circuits with bias voltage control to achieve binary-weighted current outputs.

The current DAC circuit 402, as part of the current generation unit 108, includes at least one current source, where the at least one current source comprises a set of transistors in a parallel configuration. As shown, the current DAC circuit 402 includes multiple sets of transistors arranged to produce binary-weighted currents corresponding to different bit positions in a binary representation. The current DAC circuit 402 comprises a set of transistors 402a, a set of transistors 402b, and a set of transistors 402k, where each set is configured to generate a current proportional to a respective bit position in a binary representation. The set of transistors 402a may include a single transistor configured to generate a base current I₀, the set of transistors 402b may include a pair of transistors in parallel configured to generate a current 2I₀, and the set of transistors 402k may include k-number of transistors in parallel configured to generate a current 2^{(k-1)}I₀, creating a binary-weighted current distribution that corresponds to the place values in a binary number system. Each set of transistors may be implemented using parallel transistor arrangements, where multiple transistors are connected in parallel to achieve the desired current scaling, or through transistor sizing with varying width-to-length ratios to produce different current levels. The parallel configuration enables precise current scaling through the combination of multiple unit transistors, where the total current from each set is proportional to the number of transistors in parallel and their individual characteristics.

Each set of transistors is biased by a bias voltage generator 408, which provides a bias voltage V_{b} to the gate terminals of the transistors. Each transistor of the set of transistors includes a gate terminal coupled to a common bias voltage, providing good current matching through the common bias voltage, scalable current levels through parallel transistor configuration, and simplified bias generation circuitry that may be shared across multiple current sources. The bias voltage generator 408 supplies a common bias voltage to all transistor sets, establishing the reference current levels for the binary-weighted current sources. The bias voltage generator 408 may be implemented using various bias generation circuits, including bandgap reference circuits, current mirror bias generators, resistor-based voltage dividers, or dedicated bias voltage regulators that provide stable bias voltages across process, voltage, and temperature variations. The transistor-based implementation may utilize single MOSFET devices with bias voltage control, where each transistor operates in the saturation region to function as a current source with output current determined by the gate-source voltage and transistor dimensions. Alternatively, the implementation may employ two-transistor current mirror configurations, where a reference transistor establishes the bias current and mirror transistors replicate this current with scaling factors determined by transistor size ratios.

As shown in FIG. 4, the modulated current element 400 includes memory cells for storing bit values of a digital operand that control the activation of internal switches within the current DAC circuit 402. A first memory cell 404a is coupled to internal switch S₁ₐ, a second memory cell 404b is coupled to internal switch S_{1b}, and a kth memory cell 404k is coupled to internal switch S₁₍ₖ₋₁₎. Each memory cell stores a respective bit value (b₀, b₁, through b₍ₖ₋₁₎ ) that controls the state of its associated internal switch. The memory cells function as control elements that selectively activate their respective internal switches based on the stored bit values, which in turn control the flow of current from the associated transistor sets. The memory cells may be implemented using SRAM technology for high-speed access and low power consumption during read operations, or DRAM technology for higher density storage with periodic refresh requirements. The memory cells provide direct digital control interface for storing weight values, simplified memory interface for operand storage and retrieval, and efficient bit-level activation of current sources through direct coupling to the internal switching elements.

The switching unit 406 is operatively coupled to the outputs of the internal switches and provides controlled current flow based on external control signals. The switching unit 406 includes switches S₂ₐ, S_{2b}, and S₂₍ₖ₋₁₎, which are controlled by a PWM signal xᵢ (also referred to as control signal). The switches S₂ₐ, S_{2b}, and S₂₍ₖ₋₁₎ are all controlled by the PWM signal xᵢ and are positioned between the internal switches and the output node. The switching unit 406 selectively controls the flow of current pulses from the internal switches based on the PWM signal, implementing a logical AND operation where current flows only when both the internal switch is closed (based on the memory cell bit value) and the corresponding switch in the switching unit is closed (based on the PWM signal).

The current pulses from the activated transistor sets flow through their respective internal switches (when closed based on memory cell values) and then through the switching unit 406 switches (when closed based on the PWM signal) to combine at an output node Iₒᵤₜ. This configuration enables the modulated current element 400 to generate an output current that represents the product of the PWM-encoded input and the binary-weighted value stored in the memory cells. The mathematical relationship for the output current may be expressed as Iₒᵤₜ=Σ(i=0 to k−1)bᵢ·2ⁱ·I₀·PWM(xᵢ), where bᵢ represents the bit values stored in the memory cells, 2ⁱ represents the binary weighting factors, I₀ represents the base current unit, and PWM(xᵢ) represents the pulse width modulated control signal.

The parallel transistor arrangements within each set enable fine-tuning of current levels through the selection of transistor quantities and sizes, providing flexibility in achieving desired current ratios while maintaining good matching characteristics. The common bias voltage approach simplifies the bias generation circuitry and ensures consistent current relationships across all transistor sets, reducing the complexity of bias distribution networks and improving current accuracy through shared bias references.

The integration of memory cells directly with the internal switches of the current generation circuitry enables in-memory computing functionality, where weight values may be stored locally and accessed without external data transfer operations. The memory cells may be implemented using conventional SRAM or DRAM technologies, providing compatibility with existing memory fabrication processes and enabling integration within standard memory arrays. The direct coupling between memory cells and internal switches reduces the signal path lengths and parasitic effects that could degrade switching performance, while enabling high-speed switching between different weight values through rapid memory access operations. The memory-integrated approach supports both static weight storage for inference operations and dynamic weight updates for training applications, where new weight values may be written to the memory cells to update the multiplication coefficients.

It should be noted that the modulated current element 400 shown in FIG. 4 may be connected to an integrator unit and other processing components as described with reference to FIG. 1. The integrator unit may be coupled to the output node of the switching unit to receive the controlled flow of current pulses and generate an output signal representing the multiplication result. The modulated current element configuration shown in FIG. 4 is illustrated in a reduced form for clarity and brevity, with the understanding that the complete multiplier circuit includes the integrator unit, analog-to-digital converter (ADC), and other processing components as described in FIG. 1.

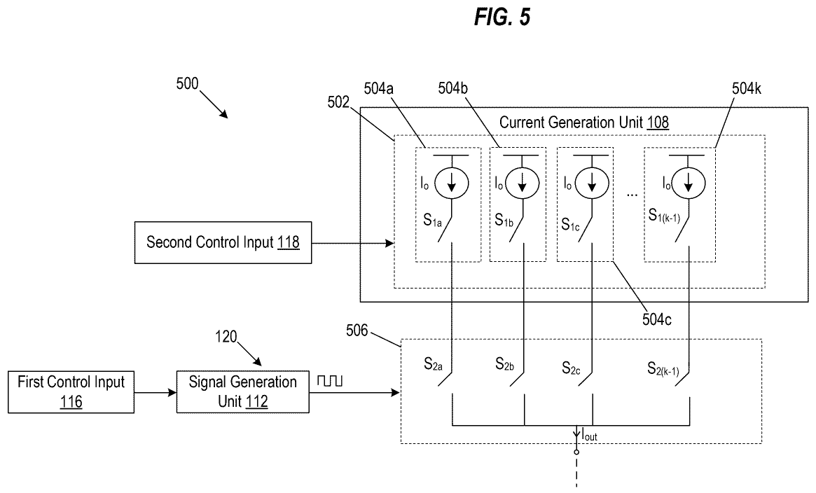

FIG. 5 is a block diagram that illustrates a modulated current element 500 with multiple current DAC circuits, in accordance with an embodiment of the disclosure. FIG. 5 is described in conjunction with elements from FIG. 1 and FIGS. 2-4. The modulated current element 500 comprises the current generation unit 108 and the signal generation unit 112, which are interconnected to provide place value control through multiple current DAC circuits and associated switching elements for flexible operand decomposition and optimized hardware utilization based on specific precision requirements. Unlike the implementations shown in FIGS. 2, 3, and 4, this embodiment decomposes both operands such that all weighting is implemented in the PWM signals rather than through weighted current sources, enabling significant transistor count reduction and area savings at the cost of increased pulse durations that may affect operational speed.

The current generation unit 108 comprises a plurality of current Digital-to-Analog (DAC) circuits 502, which includes a current Digital-to-Analog (DAC) circuit 504a, a current Digital-to-Analog (DAC) circuit 504b, a current Digital-to-Analog (DAC) circuit 504c, and a current Digital-to-Analog (DAC) circuit 504k. Each current DAC circuit of the plurality of current Digital-to-Analog (DAC) circuits 502 comprises a current source and an internal switch coupled to the current source. Each of the plurality of current Digital-to-Analog (DAC) circuits 502 is configured to generate a respective current pulse based on the second control input 118. The modular current generation architecture provides scalable design for different bit widths, simplified individual current source control, and flexible allocation of current sources based on place value requirements. In this configuration, the current sources are implemented as uniform, unweighted elements, eliminating the need for binary-weighted transistor sizing or multiple parallel transistors required in the architectures of FIGS. 2, 3, and 4, thereby achieving substantial area reduction.

The modulated current element 500 further includes a plurality of switches 506 that provides switching control for enhanced operand processing flexibility. The plurality of switches 506 comprises a second switch S₂ₐ, a second switch S_{2b}, a second switch S_{2c}, and a second switch S₂₍ₖ₋₁₎. Each switch of the plurality of switches 506 is coupled to the internal switch of a respective current DAC circuit of the plurality of current Digital-to-Analog (DAC) circuits 502, enabling independent control of each current generation path. The plurality of switches 506 are positioned to provide control over current flow from the respective current DAC circuits.

In this embodiment, the first digital operand includes a first digit component and a unit place value component corresponding to the first digit component, and the second digital operand includes a second digit component as a set of bit values and a second place value component as a set of place values corresponding to the set of bit values. The signal generation unit 112 receives the first control input 116 and generates the at least one control signal 120 based on the first control input 116. The at least one component for the first control input 116 includes the first digit component and the second place value component, enabling the signal generation unit 112 to incorporate both digit values and place value weighting in the control signal generation process. The at least one control signal 120 includes a plurality of Pulse Width Modulated (PWM) signals that control the plurality of switches 506. Each PWM signal of the plurality of PWM signals is associated with a respective pulse duration that is proportional to a product of a value of the first digit component and a respective place value of the set of place values. The PWM signal generation enables place value weighting in the time domain through pulse duration adjustment, where different place values result in proportionally scaled pulse durations for their corresponding current paths. This approach transfers all weighting responsibilities from the current domain to the time domain, allowing the use of identical current sources while achieving the required multiplication weighting through temporal control.

As shown in FIG. 5, the plurality of switches 506 (S₂ₐ, S_{2b}, S_{2c}, S₂₍ₖ₋₁₎) are controlled by the at least one control signal 120 from the signal generation unit 112, while the internal switches (S₁ₐ, S_{1b}, S_{1c}, S₁₍ₖ₋₁₎) within each current DAC circuit are controlled by the second control input 118. The at least one component for the second control input 118 includes the second digit component, where the second control input 118 includes the set of bit values that represent the second digit component. Each binary value of the set of binary values acts as a respective control signal for the internal switch of a respective current DAC circuit of the plurality of current Digital-to-Analog (DAC) circuits 502. An application of each binary value of the set of bit values to the internal switch of the respective current DAC circuit selectively activates the current source in the respective current DAC circuit of the plurality of current Digital-to-Analog (DAC) circuits 502 to generate a respective current pulse of the plurality of current pulses.

The switching unit includes the plurality of switches 506, which is configured to control the flow of each current pulse of the plurality of current pulses over the respective pulse duration to generate the first output signal 124. The dual-level switching configuration allows for selective control of current pulses generated by each of the plurality of current Digital-to-Analog (DAC) circuits 502, enabling the modulated current element 500 to perform multiplication operations based on both the first control input 116 and the second control input 118. The plurality of switches 506 provide time-domain control through PWM signals that incorporate place value weighting, while the internal switches within each current DAC circuit provide current-domain control through selective activation of current sources based on the bit values of the second digital operand.

The place value weighting may be implemented in the current domain through weighted current sources or in the time domain through weighted PWM signals. In the time domain implementation shown in FIG. 5, the place value weighting is achieved through the pulse duration adjustment of the PWM signals, where each PWM signal duration is proportional to the product of the first digit component value and the respective place value from the set of place values. This approach enables flexible operand decomposition where different bit positions may have different place value assignments, supporting arbitrary place value configurations beyond standard binary weighting. The time domain weighting approach may provide advantages in terms of simplified current source design, as the current sources may be implemented with uniform characteristics while the place value differentiation is achieved through timing control. However, this approach involves a speed-area trade-off, where the area savings achieved through uniform current sources come at the cost of longer pulse durations for higher place values, potentially reducing the maximum operational frequency compared to current-weighted implementations.

The mathematical relationship for the place value weighting in the time domain may be expressed as T_{PWM}(i)=(X×Pᵢ×Tᵤ), where T_{PWM}(i) represents the pulse duration for the i-th PWM signal, X represents the value of the first digit component, Pᵢ represents the respective place value from the set of place values of the second digital operand, and Tᵤ represents the unit time interval. The current contribution from each path may be represented as Iᵢ=(Wᵢ×I₀), where Wᵢ represents the bit value from the second digital operand and I₀ represents the base current unit. The combined effect produces a charge accumulation proportional to the product of the operands, with place value weighting achieved through the time domain scaling of the PWM signals rather than through current domain scaling of the current sources. This time-domain weighting approach eliminates the exponential scaling of transistor sizes required in binary-weighted current sources, where higher-order bits would typically require 2ⁿ times more transistors, resulting in significant area savings at the expense of proportionally longer pulse durations for higher place values.

The modulated current element 500 enables support for different precision requirements through the configurable number of current DAC circuits in the plurality of current Digital-to-Analog (DAC) circuits 502. The architecture may be scaled to accommodate various bit widths by adjusting the number of current DAC circuits and their associated switching elements. For applications requiring higher precision, additional current DAC circuits may be included with corresponding place values, while applications with lower precision requirements may utilize fewer current DAC circuits to reduce hardware complexity and power consumption. The modular design facilitates optimization of hardware utilization based on specific application needs, enabling efficient allocation of circuit resources based on the precision and performance requirements of different computational tasks.

It should be noted that the modulated current element 500 shown in FIG. 5 may be connected to an integrator unit and other processing components as described with reference to FIG. 1. The integrator unit may be coupled to the output node of the switching unit to receive the controlled flow of current pulses and generate an output signal representing the multiplication result. The modulated current element configuration shown in FIG. 5 is illustrated in a reduced form for clarity and brevity, with the understanding that the complete multiplier circuit includes the integrator unit, analog-to-digital converter (ADC), and other processing components as described in FIG. 1.

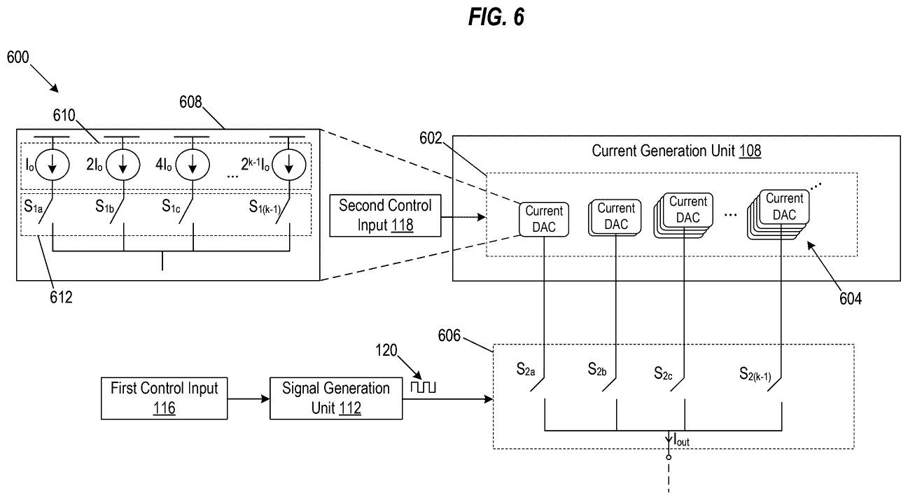

FIG. 6 is a block diagram that illustrates a modulated current element 600 with hierarchical current DAC organization, in accordance with an embodiment of the disclosure. FIG. 6 is described in conjunction with elements from FIG. 1. The modulated current element 600 comprises the current generation unit 108, the signal generation unit 112, a plurality of current Digital-to-Analog (DAC) circuits 602, a specific set of current DAC circuits 604, and a set of switches 606.

The modulated current element 600 implements multiplication where the first digital operand includes a first digit component as a set of bit values and a second place value component as a set of place values corresponding to the set of bit values, and the second digital operand includes a second digit component and a unit place value component corresponding to the second digit component. The first digital operand X is represented as X=Σᵢxᵢ·pᵢ, where xᵢ∈{0,1} represents the individual bit values that are carried as unit pulses in the PWM signals and pᵢ represents the corresponding place values that are implemented through the allocation of current DAC circuits in the current domain. The second digital operand includes a second digit component and a unit place value component corresponding to the second digit component. The second digital operand w may range from 0 to 15 in a 4-bit implementation, with its weight carried by the binary-weighted current sources within each DAC circuit, while the unit place value component provides the base scaling factor.

Unlike FIG. 5 where all weights are carried on the PWM side, the modulated current element 600 carries all weights in the current domain, with each DAC itself having binary weighted current sources that carry place values of the first digital operand, and a specific number of DACs carrying the weight of the second digit component. The PWM signals are simplified to unit pulses carrying only the set of bit values of the first operand (0 or 1), eliminating the need for complex pulse width modulation while transferring all weighting operations to the current domain. This approach enables faster operation speed due to the use of unit pulses that require minimal timing precision but comes at the cost of higher power consumption and increased area requirements for the multiple current DAC circuits needed to implement the weighting in the current domain.

The current generation unit 108 includes the plurality of current DAC circuits 602 in a specific configuration where all weighting is implemented in the current domain. The specific configuration includes a specific set of current DAC circuits 604 of the plurality of current DAC circuits 602 for each switch of the set of switches 606. A number of current DAC circuits in the specific set of current DAC circuits 604 corresponds to a respective place value of the set of place values, enabling the current domain to carry the place value weighting of the first digital operand. Each current DAC circuit 608 of the plurality of current DAC circuits 602 comprises a plurality of binary-weighted current sources 610 and a plurality of internal switches 612 respectively coupled to the plurality of binary-weighted current sources 610. The plurality of binary-weighted current sources 610 are labeled as I₀, 2I₀, 4I₀, and 2^{(k-1)}I₀, representing binary-weighted current values that carry the weight of the second digit component. The plurality of internal switches 612 are labeled as S₁ₐ, S_{1b}, S_{1c}, and S₁₍ₖ₋₁₎.

The at least one component for the second control input 118 includes the second digit component, whose weight is carried entirely by the binary-weighted current sources within each DAC circuit. The second control input 118 includes a set of bit values representing the second digit component. An application of the set of bit values to the plurality of binary-weighted current sources 610 selectively activates the plurality of binary-weighted current sources 610 in each current DAC circuit 608 of the plurality of current DAC circuits 602 to generate a respective current pulse of the plurality of current pulses. This hierarchical current generation with binary weighting enables efficient reuse of control signals across multiple DAC circuits and scalable precision through modular DAC architecture, with all weighting implemented in the current domain rather than the time domain.

The switching unit includes a set of switches 606 corresponding to the set of bit values. The at least one component for the first control input 116 includes the first digit component as simple bit values (0 or 1). The set of switches 606 includes a second switch S₂ₐ, a second switch S_{2b}, a second switch S_{2c}, and a second switch S₂₍ₖ₋₁₎. Each switch of the set of switches 606 corresponds to a respective bit value of the set of bit values, providing one-to-one correspondence between bits and switches and simplified control signal distribution for efficient bit-level switching control, where the PWM signals carry only the binary bit information without additional weighting.

Each switch of the set of switches 606 is coupled to a shorted output of the specific set of current DAC circuits 604. The at least one component for the first control input 116 includes the first digit component as unit bit values. The at least one control signal 120 includes a plurality of Pulse Width Modulated (PWM) signals that are simplified unit pulses carrying only the bit values (0 or 1) of the first operand without additional weighting. Each PWM signal of the plurality of PWM signals is associated with a respective pulse duration that corresponds to a respective bit value of the set of bit values, where the pulse is either present (for bit value 1) or absent (for bit value 0). The signal generation unit 112 receives the first control input 116 and generates the at least one control signal 120 as the plurality of PWM signals that control the set of switches 606. Each switch of the set of switches 606 is controlled by a respective PWM signal from the at least one control signal 120.

The switching unit is configured to control the flow of each current pulse of the plurality of current pulses over the respective pulse duration to generate the first output signal 124. The outputs from each specific set of current DAC circuits 604 are combined at their respective shorted outputs and connected to the corresponding switch of the set of switches 606. The shorted output configuration enables efficient current combining through shorted outputs, where multiple current DAC circuits within each specific set contribute their currents to a common node before reaching the switching elements. This arrangement provides simplified integration of multiple current sources and efficient current combining for each bit position of the first digital operand, with all place value weighting handled in the current domain through the allocation and configuration of DAC circuits.

The modulated current element 600 operates by applying the second control input 118 to the plurality of internal switches 612, which selectively activates the plurality of binary-weighted current sources 610 in each current DAC circuit 608 that carry the weight of the second digit component. The resulting currents from each specific set of current DAC circuits 604 are combined at their respective shorted outputs and controlled by the set of switches 606 based on the at least one control signal 120 from the signal generation unit 112, where the PWM signals serve as simple unit pulses carrying the bit values of the first operand. The controlled flow of current pulses is directed toward an output node for integration to generate the first output signal 124 representing a multiplication result, with all weighting operations performed in the current domain.

The architecture enables efficient multiplication when the first operand is decomposed into binary bits with place value weighting implemented entirely through the current domain configuration of grouped DAC circuits. The place value weighting is achieved through the allocation of multiple current DAC circuits to bit positions with higher place values, enabling hardware resources to be distributed proportionally to the significance of each bit position, while the PWM signals carry only simple unit pulses representing the bit values (0 or 1). The mathematical relationship for this configuration may be expressed as Vₒᵤₜ=(1/C)Σᵢxᵢ·pᵢ·I_{DAC}·Tᵤₙᵢₜ, where each contribution is proportional to the product of the bit value (carried by unit PWM pulses), the place value (implemented through DAC allocation), and the current generated by the corresponding specific set of current DAC circuits 604. This approach provides flexible operand decomposition, support for arbitrary place value assignments, and optimized hardware allocation based on the characteristics of the first digital operand, with the key distinction that all weighting is carried in the current domain rather than the time domain.

It should be noted that the modulated current element 600 shown in FIG. 6 may be connected to an integrator unit and other processing components as described with reference to FIG. 1. The integrator unit may be coupled to the output node of the switching unit to receive the controlled flow of current pulses and generate an output signal representing the multiplication result. The modulated current element configuration shown in FIG. 6 is illustrated in a reduced form for clarity and brevity, with the understanding that the complete multiplier circuit includes the integrator unit, analog-to-digital converter (ADC), and other processing components as described in FIG. 1.

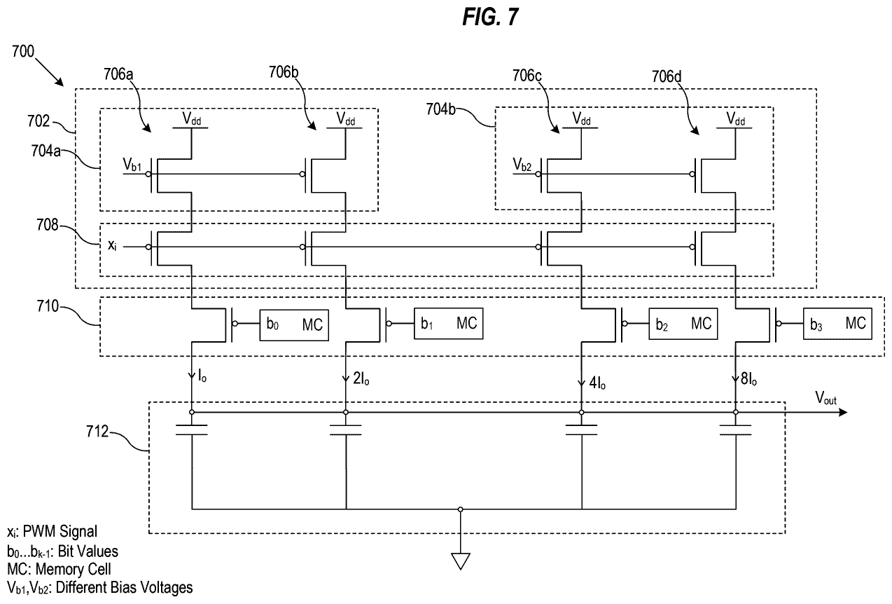

FIG. 7 is a circuit diagram that illustrates a multiplier circuit 700 with grouped current sources using differential biasing for area reduction, in accordance with an embodiment of the disclosure. FIG. 7 is described in conjunction with elements from FIG. 1 and FIGS. 2-6. The multiplier circuit 700 demonstrates an alternative approach to achieving binary-weighted current outputs through differential biasing of current source groups rather than through transistor sizing or replication of unit elements. The multiplier circuit 700 comprises a current Digital-to-Analog Converter (DAC) circuit 702, a switching unit 710, and an integrator unit 712, which are interconnected to provide area-efficient current generation through grouped bias voltage control.

The current Digital-to-Analog Converter (DAC) circuit 702 comprises a plurality of current sources in a plurality of groups, where each current source of the plurality of current sources is a binary-weighted current source that corresponds to a respective place value of a respective bit of one of the first digital operand or the second digital operand. The current DAC circuit 702 includes multiple current sources arranged in groups, such as a first group 704a and a second group 704b for 4-bit implementation as shown. Each group of the plurality of groups includes at least one current source of the plurality of current sources, enabling flexible allocation of current sources based on the binary weighting requirements and area optimization considerations. As shown, within these groups, the circuit includes a current source 706a and a current source 706b in the first group 704a, and a current source 706c and a current source 706d in the second group 704b.

The at least one current source in each group of the plurality of groups includes a specific transistor-based circuit that is biased with a different bias voltage. Each current source in the first group 704a is biased with a first bias voltage V_{b1}, while each current source in the second group 704b is biased with a second bias voltage V_{b2}. The different bias voltage for each group of the plurality of groups is such that a current output of each current source of the at least one current source in a respective group of the plurality of groups is proportional to the respective place value corresponding to a respective current source of the plurality of current sources. The different bias voltages applied to each group enable the current sources to generate binary-weighted currents corresponding to different place values of a digital operand without requiring transistor size scaling or unit element replication.

The current sources may generate different weighted current levels through the application of the different bias voltages. For instance, current sources in the first group 704a may generate base currents (I₀ and 2I₀), while current sources in the second group 704b may generate higher-weighted currents (4I₀ and 8I₀) through the application of the different bias voltage. The bias voltage differential enables precise current scaling where the current output from each group is proportional to the applied bias voltage and the transistor characteristics, allowing for binary weighting to be achieved through bias control rather than through physical transistor scaling.

The current sources are coupled to internal switches 708, which selectively activate the current sources based on bit values of a digital input. A control signal xᵢ is applied to the internal switches 708 to control the activation of the current sources. The internal switches 708 may be implemented using MOSFET switches, transmission gates, or other switching elements that provide low on-resistance and high off-isolation to maintain current accuracy. The control signal xᵢ functions as a pulse width modulated signal that determines the duration of current flow from the activated current sources, enabling time-domain representation of one multiplication operand.

The switching unit 710 is operatively coupled to the outputs of the internal switches 708 and includes multiple switches controlled by bit values b₀, b₁, b₂, and b₃, along with associated memory cells (MC) that store these bit values. The switching unit 710 provides selective activation of individual current sources based on the stored bit values, where each bit value controls the activation state of its corresponding current source. The memory cells may be implemented using SRAM technology for high-speed access and low power consumption, or alternative memory technologies such as DRAM or non-volatile memory depending on the application requirements. The bit values stored in the memory cells represent the binary representation of the second digital operand, enabling direct digital control of the current source activation.

The outputs from the switching unit 710 are combined and flow toward the integrator unit 712. The integrator unit 712 comprises capacitors connected between the output node and ground, where charge accumulation occurs based on the controlled flow of current pulses. The integrator unit 712 accumulates charge to generate an output voltage Vₒᵤₜ that represents the result of the multiplication operation. The accumulated charge generates an output voltage Vₒᵤₜ that is proportional to the product of the input operands, where the voltage relationship may be expressed as Vₒᵤₜ=(I×T)/C, with I representing the combined current from activated sources, T representing the pulse duration from the control signal xᵢ, and C representing the capacitance of the integrator unit 712.

The circuit operates by generating current pulses through the current sources based on the stored bit values, with the pulse width modulated signal xᵢ controlling the duration of current flow. The binary-weighted nature of the current sources, achieved through the grouping and differential biasing scheme, ensures that each bit position contributes the appropriate weighted value to the final multiplication result. The integrator unit 712 accumulates these weighted current contributions over time to produce the output voltage Vₒᵤₜ proportional to the product of the input operands.

The differential biasing approach provides significant area efficiency advantages compared to conventional current DAC implementations that rely on unit element replication. Prior art implementations of current DAC typically replicate unit DAC elements to realize multiples, such as 2I₀=Iᵤ+Iᵤ and 4I₀=Iᵤ+Iᵤ+Iᵤ+Iᵤ, which consumes significant area. For an 8-bit implementation, the area efficiency analysis demonstrates dramatic reductions in transistor count through the use of independent bias voltages. A conventional implementation requires 255×Aᵤ area, where Aᵤ is the unit area of unit element that produces Iᵤ. A “1 Bias” configuration, equivalent to conventional unit element replication, requires 512T+1 V_{b} line, where T represents unit transistor area. A “2 Bias” configuration reduces the requirement to 60T+2 V_{b} lines, providing substantial area savings. A “4 Bias” configuration further reduces the requirement to 24T+4 V_{b} lines, and an “8 Bias” configuration requires only 16T+8 V_{b} lines, representing a dramatic reduction in transistor count from 512T to 16T.

The area reduction is achieved by replacing the replication of unit current sources with independent bias voltage generation for each current level. Instead of implementing higher-weighted currents through parallel combinations of unit current sources (such as 2I₀=I₀+I₀, 4I₀=I₀+I₀+I₀+I₀), the differential biasing approach generates each current level through a single transistor or small transistor group with an appropriately scaled bias voltage. This approach dramatically reduces the total transistor count and chip area required for multi-bit current DAC implementations.

The trade-off associated with increasing the number of independent bias lines involves a reduction in matching accuracy between current sources. Conventional unit element replication provides excellent current matching because all current sources are identical and operate under the same bias conditions. The differential biasing approach may introduce matching variations because different current sources operate under different bias conditions, potentially leading to current ratio errors that affect the accuracy of the binary weighting. However, the area savings achieved through the differential biasing approach may outweigh the matching accuracy trade-offs for many applications, particularly those where moderate precision requirements allow for some current ratio variations.

The bias voltage generation for the differential biasing approach may be implemented using various circuit techniques, including resistor ladder networks, current mirror bias generators, or dedicated voltage regulators for each bias level. The bias voltage accuracy and stability directly affect the current ratio accuracy, making the bias generation circuitry a critical component for maintaining multiplication accuracy. Temperature and process variation compensation may be incorporated into the bias generation circuits to improve current ratio stability across operating conditions.

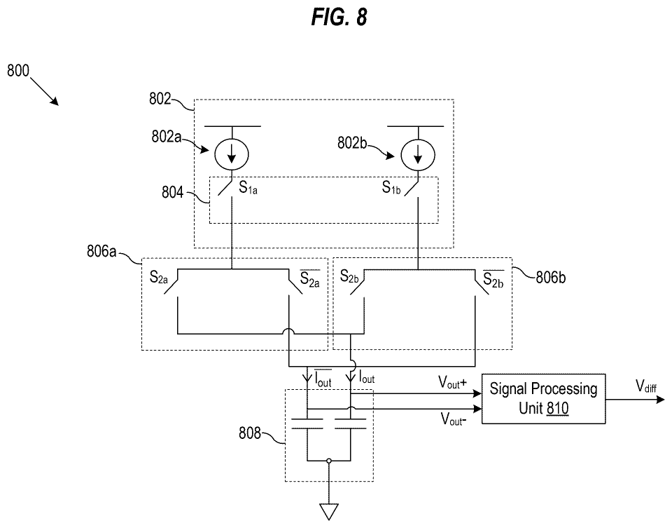

FIG. 8 is a circuit diagram that illustrates a multiplier circuit 800 with complementary switch pairs for differential output generation, in accordance with an embodiment of the disclosure. FIG. 8 is described in conjunction with elements from FIGS. 1-7. The multiplier circuit 800 implements a differential signal generation approach that provides enhanced noise immunity and improved dynamic range compared to single-ended output configurations. The multiplier circuit 800 comprises a current generation unit 802, a switching unit comprising switch pairs 806a-806b, and an integrator unit 808, which are interconnected to provide complementary signal processing through paired switching elements that direct current pulses to separate capacitive integration paths.

The current generation unit 802 comprises a plurality of current sources and a plurality of internal switches 804 respectively coupled to the plurality of current sources. The current generation unit 802 includes a first current source 802a and a second current source 802b, where each current source may be implemented using transistor-based current mirror circuits, cascode current source configurations, or other current generation topologies that provide stable current outputs. Each of the first current source 802a and the second current source 802b is coupled to a respective internal switch from the plurality of internal switches 804. The plurality of internal switches 804 includes switches S₁ₐ and S_{1b}, which may be implemented using MOSFET switches, transmission gates, or analog multiplexers that provide selective activation of the current sources based on control signals representing digital operand values.

The switching unit comprises a plurality of switch pairs, specifically a first switch pair 806a and a second switch pair 806b. An input to each switch pair of the plurality of switch pairs is coupled to a respective internal switch of the plurality of internal switches 804. The first switch pair 806a includes two switches, with one switch labeled S₂ₐ and another switch labeled S̅₂̅ₐ̅. Similarly, the second switch pair 806b includes two switches, with one switch labeled S_{2b} and another switch labeled S̅_̅{̅2̅b̅}̅. The input to the first switch pair 806a is coupled to the internal switch S₁ₐ associated with the first current source 802a, while the input to the second switch pair 806b is coupled to the internal switch S_{1b} associated with the second current source 802b.

The at least one control signal includes a respective pair of complementary signals for each switch pair of the plurality of switch pairs. Each switch pair of the plurality of switch pairs comprises a first switch for a first signal of the respective pair of complementary signals and a second switch for a second signal of the respective pair of complementary signals. The switching unit is configured to receive complementary control signals, where for each switch pair, a first switch (S₂ₐ or S_{2b}) is controlled by a first signal, while a second switch (S̅₂̅ₐ̅ or S̅_̅{̅2̅b̅}̅) is controlled by a complementary second signal. The complementary signals may be generated such that when one signal is high, the corresponding complementary signal is low, ensuring that current from each current source is directed to only one of the two integration paths at any given time.

The integrator unit 808 comprises a pair of capacitors connected between the respective shorted outputs and a ground node. Outputs of the first switch from each switch pair of the plurality of switch pairs is shorted and coupled to a first capacitor of the pair of capacitors. Outputs of the second switch from each switch pair of the plurality of switch pairs is shorted and coupled to a second capacitor of the pair of capacitors. The first capacitor is connected to the shorted outputs of the first switches (S₂ₐ and S_{2b}), while the second capacitor is connected to the shorted outputs of the second switches ((S̅₂̅ₐ̅ and S̅_̅{̅2̅b̅}̅). Current flows Iₒᵤₜ are indicated at the nodes where the capacitors accumulate charge, generating a differential voltage output Vₒᵤₜ⁺ at the first capacitor and Vₒᵤₜ⁻ at the second capacitor.

An application of the respective pair of complementary signals to each switch pair of the plurality of switch pairs selectively controls the flow of the plurality of current pulses towards the pair of capacitors to generate the first output signal (Vₒᵤₜ⁺) at the first capacitor and a second output signal (Vₒᵤₜ⁻) at the second capacitor. The second output signal is different from the first output signal. The complementary switching arrangement enables the circuit to generate both a first output signal and a second output signal at the integrator unit 808. The application of complementary control signals to the switch pairs selectively directs current pulses from the current sources to either the first capacitor or the second capacitor, allowing for differential signal generation that represents the result of a multiplication operation.

The mathematical relationships for the differential output generation may be expressed as Vₒᵤₜ⁺=Σ(xᵢ·aᵢ)/C and Vₒᵤₜ⁻=Σ((k−xi)·aᵢ)/C, where xᵢ represents the input operand values, aᵢ represents scaling factors corresponding to the current source weights, k represents a constant related to the operand range, and C represents the capacitance value. The differential voltage between the two outputs may be calculated as V_{diff}=Vₒᵤₜ⁺−Vₒᵤₜ⁻=Σ(2xᵢ−k) ·aᵢ/C, providing a differential representation of the multiplication result that offers improved noise rejection and enhanced dynamic range.

The complementary approach implements a multiplication strategy where for operands x and w, the circuit computes both p=x·w and m=(N−x)·w, where N represents the maximum value range of the operand x. The differential result calculation follows the relationship: p−m=x·w−(N−x)·w=2x·w−N·w. This approach enables the final multiplication result to be obtained through differential signal processing, where the desired product x·w may be extracted from the differential signals through the relationship x·w=(p−m+N·w)/2. The complementary computation provides inherent common-mode noise rejection, as noise sources that affect both signal paths equally are cancelled in the differential operation.

The differential arrangement provides several advantages over single-ended output configurations. The noise immunity is enhanced because common-mode noise sources, such as power supply variations, substrate noise, or electromagnetic interference, affect both output signals similarly and are rejected in the differential measurement. The dynamic range is effectively doubled for ADC input because the differential voltage swing is twice the single-ended voltage swing for the same current and capacitance values. The differential signals may be directly interfaced to differential ADC inputs, eliminating the need for single-ended to differential conversion circuits and reducing signal conditioning complexity.

In various embodiments of the disclosure, the multiplier circuit 800 further comprises a signal processing unit 810 configured to generate a third output signal V_{diff} based on the first output signal Vₒᵤₜ⁺ and the second output signal Vₒᵤₜ⁻. The third output signal V_{diff} represents the result of the multiplication operation between the first digital operand and the second digital operand. The signal processing unit 810 may be implemented using differential amplifiers, analog subtraction circuits, or digital signal processing blocks that operate on the digitized versions of the first output signal and the second output signal. The signal processing unit 810 enables differential signal processing for improved accuracy, noise cancellation through signal subtraction, and enhanced dynamic range in the final output. The third output signal may be generated through analog subtraction of the two differential signals, digital subtraction after separate ADC conversion of each signal, or through direct differential ADC conversion that produces the difference signal directly in the digital domain.

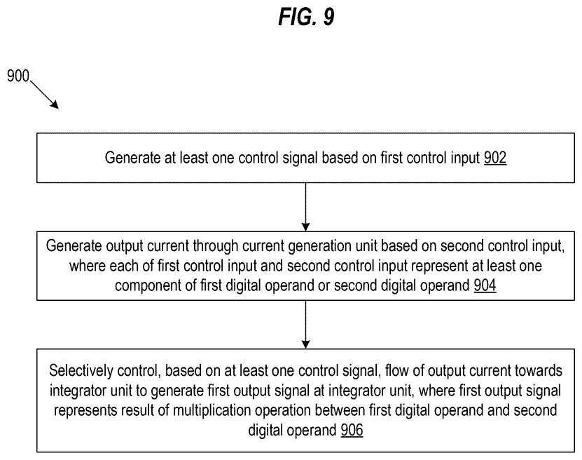

FIG. 9 is a flowchart 900 that illustrates a method for performing a multiplication operation using current-time domain processing, in accordance with an embodiment of the disclosure. FIG. 9 is described in conjunction with elements from FIGS. 1-8. The flowchart 900 demonstrates a systematic approach to implementing multiplication operations through the combination of time-domain and current-domain signal processing techniques. The method enables efficient analog domain multiplication while maintaining digital input and output interfaces, providing advantages including reduced computational complexity compared to digital methods and scalable performance with technology advances.

The flowchart 900 begins with an operation 902, where at least one control signal 120 is generated based on a first control input 116. The operation 902 implements time-domain signal generation where the first control input 116, representing at least one component of a first digital operand, is converted into the at least one control signal 120 through pulse width modulation or other time-domain encoding techniques. The at least one control signal 120 may be implemented as a Pulse Width Modulated (PWM) signal where the pulse duration corresponds to the value of the first digital operand component. The signal generation process may utilize Digital-to-Time Converter (DTC) circuits, delay-line based architectures, or counter-based PWM generators that provide precise time-domain representation of digital values with scalability across different technology nodes.

The flowchart 900 then proceeds to an operation 904, where an output current is generated through the current generation unit 108 based on a second control input 118, where each of the first control input 116 and the second control input 118 represent at least one component of a first digital operand or a second digital operand. The operation 904 implements current-domain signal generation where the second control input 118 is converted into weighted current pulses through selective activation of current sources. The current generation unit 108 may comprise binary-weighted current sources, unit or identical current sources, array of current DACs, or transistor-based current generation circuits that produce currents proportional to the digital value represented by the second control input 118. The output current magnitude is determined by the selective activation of current sources based on the bit values of the second digital operand, enabling direct conversion from digital representation to analog current domain.

The flowchart 900 then moves to an operation 906, where the flow of the output current towards the integrator unit 106 is selectively controlled based on the at least one control signal 120 to generate the first output signal 124 at the integrator unit 106, where the first output signal 124 represents a result of a multiplication operation between the first digital operand and the second digital operand. The operation 906 implements the controlled integration process where the output current flows to the integrator unit 106 only during specific time intervals determined by the at least one control signal 120. The selective control creates a logical AND operation between the time-domain signal from the operation 902 and the current-domain signal from the operation 904, enabling the multiplication operation to be performed through charge accumulation on capacitive elements within the integrator unit 106.

The method combines time-domain processing through control signals with current-domain processing through the current generation unit 108 to perform multiplication in the analog domain while operating on digital operands. The time-domain processing encodes one digital operand as pulse width or pulse duration, while the current-domain processing encodes another digital operand as weighted current magnitude. The combination of these two signal domains through controlled switching and integration enables the multiplication operation to be performed without requiring conventional digital multiplication circuits, potentially offering advantages in speed, power consumption, and area efficiency compared to traditional digital arithmetic units.

The mathematical operation yⱼ=Σᵢxᵢwᵢⱼ is realized through this process by extending the basic multiplication method to multiple operand pairs. For a single multiplication operation, the method implements the relationship y=x×w, where x represents the first digital operand encoded in the time domain and w represents the second digital operand encoded in the current domain. The multiply-accumulate operation yⱼ=Σᵢxᵢwᵢⱼ may be achieved by repeating the multiplication method for multiple operand pairs (xᵢ, wᵢⱼ) and accumulating the results through parallel integration on shared capacitive elements or through sequential accumulation with controlled reset operations between individual multiplication cycles.

The method enables efficient implementation of neural network operations, digital signal processing algorithms, and other computational tasks that require large numbers of multiply-accumulate operations. The approach may provide significant performance advantages for applications such as convolution operations in convolutional neural networks, matrix multiplication in fully connected layers, or filter operations in digital signal processing systems. The analog domain processing may enable higher computational throughput while maintaining compatibility with digital data formats through the digital input and output interfaces.

The integration process in the operation 906 follows the mathematical relationship Vₒᵤₜ=(I×T)/C, where I represents the output current magnitude determined by the second control input 118, T represents the pulse duration determined by the first control input 116, and C represents the capacitance value of the integrator unit 106. The charge accumulation during the controlled current flow period produces a voltage signal that is proportional to the product of the two digital operands, effectively implementing analog multiplication through the physical process of charge integration. The first output signal 124 generated at the integrator unit 106 provides an analog representation of the multiplication result that may be converted to digital form through analog-to-digital conversion for compatibility with downstream digital processing systems.

The method may support multiple precision implementations by adjusting the resolution of the time-domain and current-domain signal generation processes. Higher precision operations may utilize longer pulse width ranges and more precise current source weighting, while lower precision operations may enable faster processing through reduced timing requirements and simplified current generation circuits. The method may be implemented using various semiconductor technologies and may scale with advances in technology nodes, particularly benefiting from improvements in switching speed and current source accuracy that enable higher operational frequencies and improved multiplication precision.

FIG. 10 is a block diagram that illustrates a circuit generation workflow 1000 for implementing multiplication operations using current-time domain processing, in accordance with an embodiment of the disclosure. FIG. 10 is explained in conjunction with elements from FIGS. 1-9. The circuit generation workflow 1000 demonstrates systematic operand decomposition and modular circuit construction that enables generation of thousands of circuit design variations beyond those shown in FIGS. 2-8. The circuit generation workflow 1000 comprises a first operand module 1002, a second operand module 1004, a multiplication module 1006, and a circuit configuration block 1008, which provide a structured approach to operand representation and modular processing architecture through decomposition strategies and transformation approaches.

The first operand module 1002 represents a first digital operand X through operand decomposition as X=Σ(i=1 to M)pᵢ·xᵢ, where xᵢ represents digit values and pᵢ represents corresponding place values. This decomposition enables flexible representation in various number base systems, where digit values xᵢ may range from 0 to (base−1) and place values pᵢ correspond to powers of the chosen base. For binary implementations as shown in FIG. 2, the second digital operand decomposes into bit values controlling the plurality of binary-weighted current sources 204, where each bit represents a digit component with binary place values (2⁰, 2¹, 2², etc.). The decomposition extends to non-binary bases, enabling quaternary systems with digit values 0-3 and place values (4⁰, 4¹, 4², etc.), or octal systems with digit values 0-7 and place values (8⁰, 8¹, 8², etc.).

The second operand module 1004 represents a second digital operand Y as Y=Σ(j=1 to N)qⱼ·yⱼ, where yⱼ represents digit values and qⱼ represents place values. The second operand module 1004 may implement different decomposition strategies compared to the first operand module 1002, enabling asymmetric optimization where operands are decomposed according to their specific characteristics. For instance, in FIG. 5, the plurality of current Digital-to-Analog (DAC) circuits 502 each handle individual digit components, while in FIG. 6, the specific set of current DAC circuits 604 are grouped according to place values, demonstrating how operand decomposition maps to different hardware arrangements for optimal resource utilization.

The multiplication module 1006 performs multiplication X·Y=Σ(i=1 to M)Σ(j=1 to N)pᵢ·xᵢ·qⱼ·yⱼ, representing the double summation of products between digit components and place values from both operands. This mathematical relationship directly corresponds to the physical implementation shown in FIGS. 2-6, where each term pᵢ·xᵢ·qⱼ·yⱼ represents a partial product realized through the combination of current generation and pulse width modulation. The workflow enables optimization strategies where constant place values pᵢ and qⱼ are known during hardware implementation, allowing transformation stages to be combined into single operations with reduced hardware complexity.

The circuit configuration block 1008 comprises an I-module 1010, a T-module 1012, and an integrator module 1014, implementing the systematic workflow: operand decomposition→current-domain transformation (I-module)→time-domain transformation (T-module)→integration. The I-module 1010 implements current domain processing corresponding to the current generation units shown in FIGS. 2-6, where weighted current generation represents operand components. The T-module 1012 implements time domain processing corresponding to the signal generation units that produce PWM signals for controlling switching units. The integrator module 1014 corresponds to the integrator units shown throughout the figures that accumulate charge to generate output voltages proportional to X·Y.

The I-module 1010 implements current domain processing where multiple current sources may be combined into single transformation blocks when place values are constant. In FIG. 2, the plurality of binary-weighted current sources 204 are combined at the shorted node 210, demonstrating how individual current contributions merge into a unified current processing block. For non-binary implementations, digit-specific current sources generate currents proportional to digit values, where each digit position requires current sources capable of generating currents from 0 to (base−1)×I₀. This extends the binary current sources (I₀, 2I₀, 4I₀) shown in FIG. 2 to multi-level current sources for quaternary (0, I₀, 2I₀, 3I₀) or octal (0 through 7I₀) implementations. Hardware efficiency is achieved by combining I-modules when place value transformations pᵢ are performed previously, enabling block merging to form single operations.

The T-module 1012 implements time domain processing through PWM generation with time expansion and pulse replication capabilities. Time expansion scales a base time unit Tᵤ to Tᵤ·yⱼ based on digit values, corresponding to how the signal generation unit 112 in FIG. 1 generates PWM signals with pulse durations proportional to the first control input 116. Pulse replication extends this by replicating the expanded pulse pₓᵢ times for place value scaling, resulting in the combined T-unit formula: T_{combined}=Tᵤ·yⱼ·pₓᵢ. This approach provides an alternative to the current domain weighting shown in FIGS. 2-6, where place values are implemented through timing control rather than current scaling. When both pₓᵢ and qⱼ transformations are required, they may be combined as a single transformation with the product pₓᵢ·qⱼ, reducing hardware complexity.

The modular construction enables different combinations of I-module 1010 and T-module 1012 components through three primary strategies. Digit-based scaling processes individual digit values separately, as shown in FIG. 5 where each current Digital-to-Analog (DAC) circuit 504a-504k handles individual digits. Place-based scaling implements place values through hardware weighting, as demonstrated in FIG. 6 where the specific set of current DAC circuits 604 are grouped according to place values. Mixed strategies combine both approaches, where transformation stages may merge digit-based and place-based scaling operations when place values are known constants during implementation, enabling significant hardware optimization through block consolidation.

For non-binary implementations, digit values extend beyond binary (0,1) to quaternary (0-3) or octal (0-7) systems. Quaternary implementations require current sources generating four distinct levels (0, I₀, 2I₀, 3I₀) for each digit position. These may be implemented through binary decomposition with internal DAC circuits, where a 2-bit internal DAC generates the four current levels, or through parallel current source arrays with unit current elements. The approach extends the binary-weighted current sources 204 shown in FIG. 2 to multi-level current generation, enabling optimization based on the trade-off between hardware complexity and processing speed.

Three architectural variations provide different performance-area trade-offs. Digit-parallel architecture processes multiple digits simultaneously, extending the parallel switching approach shown in FIG. 3 where the plurality of switches 308 control individual current sources. Each digit position has separate PWM control and independent current sources with place value weighting, providing highest processing speed through parallel operation while requiring increased hardware complexity. Digit-serial architecture processes digits sequentially with shared hardware resources, using a single current source with programmable weighting reconfigured for each digit position, reducing hardware complexity at the cost of increased processing time. Hybrid architecture combines parallel and serial approaches, with multiple current sources handling subsets of digits, providing configurable processing modes based on operand characteristics and performance requirements.

Multi-level switches handle non-binary digit values requiring more than simple on/off control. These include analog switches with variable conductance providing proportional current flow, current steering circuits with multiple output levels, or digital-to-analog conversion at the switch level. This extends the binary switching shown in FIGS. 2-6 to handle quaternary or octal digit values directly without requiring conversion to binary representation, enabling direct processing of higher-radix number systems with improved efficiency.

Place value weighting may be implemented in current domain or time domain, providing flexibility in hardware optimization. Current domain weighting scales current sources by place values, where LSB current sources generate I₀×digit_value, next digit sources generate B×I₀×digit_value for base B systems, and MSB sources generate B^{(N-1)}×I₀×digit_value. This extends the binary weighting (I₀, 2I₀, 4I₀, 2^{(k-1)}I₀) shown in FIG. 2 to arbitrary base systems. Time domain weighting scales PWM signals by place values, where LSB PWM has pulse_width×1, next digit PWM has pulse_width×B, and MSB PWM has pulse_width×B^{(N-1)}, providing place value differentiation through timing control rather than current scaling. The choice between current and time domain weighting enables optimization based on precision requirements, speed constraints, and area limitations.

The integrator module 1014 generates output voltage Vₒᵤₜ proportional to X·Y through charge accumulation from the I-module 1010 and T-module 1012. This corresponds to the integrator units shown throughout FIGS. 1-8, where Vₒᵤₜ=(1/C)∫I(t)dt represents accumulation of current contributions over time periods determined by PWM control, with current magnitude determined by operand decomposition and digit processing strategies. The circuit generation workflow 1000 demonstrates how systematic operand decomposition enables thousands of circuit variations through different combinations of digit representations, place value assignments, current source arrangements, switching configurations, and integration strategies, allowing optimization based on precision needs, speed requirements, power consumption constraints, and area limitations while maintaining the fundamental current-time domain processing approach.

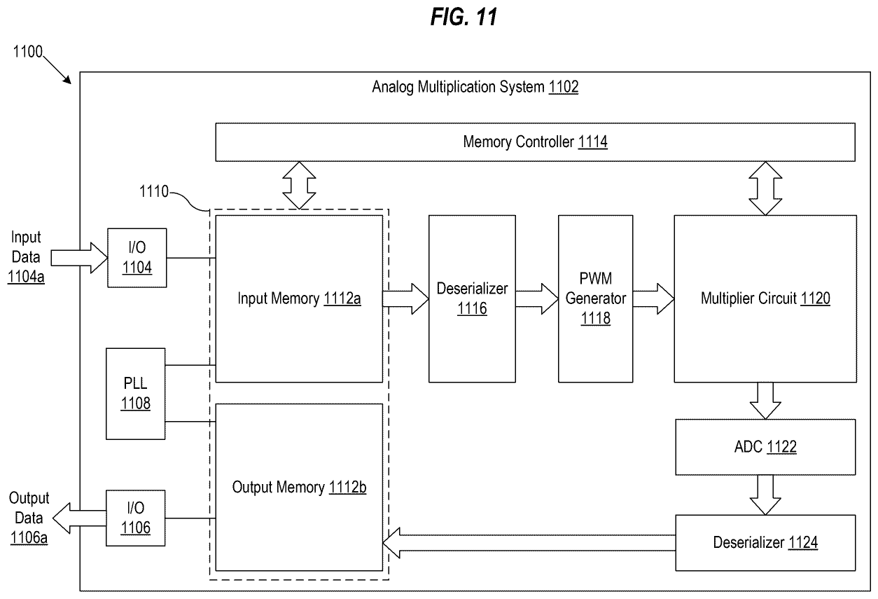

FIG. 11 is a block diagram that illustrates an analog multiplication system with memory units and processing components, in accordance with an embodiment of the disclosure. FIG. 11 is described in conjunction with elements from FIGS. 1-10. The block diagram 1100 shows an analog multiplication system 1102 that integrates memory storage, signal processing, and multiplication operations within a unified architecture. The analog multiplication system 1102 comprises a memory unit 1110 configured to store at least one of a first digital operand and a second digital operand, and a multiplier circuit 1120 that implements current-time domain processing for performing multiplication operations on the stored operands, similar to the multiplier circuit 102 shown in FIG. 1. The analog multiplication system 1102 demonstrates how the multiplier circuit may be integrated with memory systems to enable in-memory computing (IMC) or near-memory computing (NMC) functionality, reducing data movement overhead and improving computational efficiency through co-located processing and storage elements.

The analog multiplication system 1102 includes an input/output interface 1104 configured to receive input data 1104a from external sources or upstream processing systems. The input/output interface 1104 may be implemented using various communication protocols including parallel data buses, serial communication interfaces, memory-mapped I/O, or high-speed differential signaling standards that enable efficient data transfer between the analog multiplication system 1102 and external devices. The input data 1104a may represent digital operands for multiplication operations, control parameters for system configuration, or streaming data for real-time processing applications such as neural network inference or digital signal processing tasks, similar to the first control input 116 and second control input 118 described in FIG. 1.

The analog multiplication system 1102 further includes an input/output interface 1106 configured to provide output data 1106a to external systems or downstream processing elements. The input/output interface 1106 may utilize similar communication protocols as the input/output interface 1104, enabling bidirectional data flow and system integration within larger computational architectures. The output data 1106a represents the results of multiplication operations performed by the analog multiplication system 1102, which may be provided in digital format for compatibility with conventional digital processing systems or for storage in external memory systems, analogous to the digital output 130 generated by the ADC 114 in FIG. 1.

A phase-locked loop (PLL) 1108 provides timing signals for synchronization of operations within the analog multiplication system 1102. The phase-locked loop (PLL) 1108 may be implemented using various PLL architectures including charge-pump PLLs, voltage-controlled oscillator (VCO) based systems, or digital PLLs that provide stable clock signals with low jitter and precise frequency control. The phase-locked loop (PLL) 1108 generates timing references for coordinating data transfer operations, PWM signal generation similar to the at least one control signal 120 in FIG. 1, ADC conversion timing, and memory access cycles, ensuring synchronized operation across all components of the analog multiplication system 1102. The timing synchronization provided by the phase-locked loop (PLL) 1108 may be distributed through clock distribution networks, buffered clock signals, or differential clock pairs that maintain timing integrity across the system.

The memory unit 1110 comprises an input memory 1112a and an output memory 1112b that provide storage for digital operands and processing results. The input memory 1112a may be configured to store input operands received through the input/output interface 1104, while the output memory 1112b may be configured to store processed results before they are provided through the input/output interface 1106. The memory unit 1110 may be implemented using various memory technologies including static random-access memory (SRAM) for high-speed access and low power consumption, dynamic random-access memory (DRAM) for high-density storage with refresh requirements, or non-volatile memory technologies such as flash memory, magnetoresistive RAM (MRAM), or phase-change memory (PCM) for persistent storage of weight values or configuration parameters.

A memory controller 1114 is operatively coupled to the memory unit 1110 and manages data storage and retrieval operations for both the input memory 1112a and the output memory 1112b. The memory controller 1114 may implement various memory management functions including address generation, data routing, refresh control for DRAM implementations, error correction coding (ECC) for data integrity, and access arbitration for multiple concurrent memory requests. The memory controller 1114 coordinates data flow within the analog multiplication system 1102 by managing the transfer of operands from the input memory 1112a to processing elements and the storage of results in the output memory 1112b. Output lines from the memory unit 1110 are operatively coupled to at least one of the current generation unit 108 and the signal generation unit 112 of the multiplier circuit 1120, enabling direct access to stored operands without external data transfer operations, similar to the architecture shown in FIG. 1.

As shown in FIG. 11, the input data 1104a from the input/output interface 1104 is provided to the input memory 1112a for storage and subsequent processing. A deserializer 1116 is coupled to the input memory 1112a and converts serial data into parallel format for efficient processing by downstream components. The deserializer 1116 may be implemented using shift register circuits, parallel-to-serial conversion logic, or dedicated deserializer circuits that handle various data formats and communication protocols. The deserializer 1116 enables the analog multiplication system 1102 to interface with serial communication systems while providing parallel data access for high-speed internal processing operations.

The deserializer 1116 provides data to a pulse width modulation generator 1118, which generates pulse width modulated signals based on the received data. The pulse width modulation generator 1118 may be implemented using Digital-to-Time Converter (DTC) circuits, counter-based PWM generators, delay-line based architectures, or voltage-controlled delay circuits that provide precise time-domain signal generation. The pulse width modulation generator 1118 converts digital operand values into PWM signals where the pulse duration corresponds to the operand magnitude, enabling time-domain representation of multiplication operands for the current-time domain processing approach implemented by the multiplier circuit 1120, similar to how the signal generation unit 112 generates the at least one control signal 120 in FIG. 1.

The pulse width modulation generator 1118 is operatively coupled to the multiplier circuit 1120, which receives PWM signals from the pulse width modulation generator 1118 and performs multiplication operations in the analog domain. The multiplier circuit 1120 comprises a signal generation unit configured to generate at least one control signal based on a first control input, a current generation unit configured to generate a plurality of current pulses based on a second control input, a switching unit operatively coupled to the current generation unit, and an integrator unit coupled to an output node of the switching unit, similar to the architecture of multiplier circuit 102 shown in FIG. 1 which includes signal generation unit 112, current generation unit 108, switching unit 110, and integrator unit 106. Each of the first control input and the second control input represents at least one component of the first digital operand or the second digital operand, analogous to the first control input 116 and second control input 118 in FIG. 1. The switching unit is configured to selectively control, based on the at least one control signal, a flow of the plurality of current pulses towards the integrator unit to generate a first output signal at the integrator unit, and the first output signal represents a result of a multiplication operation between the first digital operand and the second digital operand, similar to how the switching unit 110 controls current flow to generate the first output signal 124 at the integrator unit 106 in FIG. 1. The multiplier circuit 1120 may implement any of the architectures described in FIGS. 1-8, including the modulated current element (MCE) configurations shown in FIGS. 2-6, the grouped current source implementation of FIG. 7, or the differential output generation approach of FIG. 8.

The multiplier circuit 1120 may be co-located on the same die as the memory unit 1110 or embedded within the physical layout of memory arrays to minimize interconnect delays and reduce power consumption through proximity. The co-location approach enables the multiplier circuit 1120 to access stored operands directly from memory cells without requiring external data transfer operations, implementing in-memory computing (IMC) functionality where computation occurs at the location of data storage. Alternatively, the multiplier circuit 1120 may be implemented as near-memory computing (NMC) elements positioned in close proximity to memory arrays while maintaining separate processing and storage regions. The integrator unit within the multiplier circuit 1120 may be implemented using any of the configurations described in FIGS. 1-8, including the common capacitor approach connected between the output node 122 and ground node 126 as shown in FIG. 1, the parallel array of capacitors described in the claims, or the differential capacitor pair configuration shown in FIG. 8.

The multiplier circuit 1120 is coupled to an analog-to-digital converter 1122, which converts the analog output signal from the multiplier circuit 1120 into a digital format suitable for storage and further processing, similar to the ADC 114 in FIG. 1 that converts the first output signal 124 to a digital output 130. The analog-to-digital converter 1122 may be implemented using various ADC architectures including successive approximation register (SAR) ADCs for moderate speed and precision requirements, sigma-delta ADCs for high precision applications, flash ADCs for high-speed conversion, or pipeline ADCs for balanced speed and precision characteristics. The analog-to-digital converter 1122 enables the analog multiplication system 1102 to provide digital output results while performing multiplication operations in the analog domain, combining the efficiency advantages of analog processing with the compatibility requirements of digital systems.

The analog-to-digital converter 1122 provides the converted digital signal to a deserializer 1124, which processes the digital signal for output formatting and protocol conversion. The deserializer 1124 may implement various signal processing functions including data formatting, protocol conversion, error detection and correction, or signal conditioning to match the requirements of downstream systems or external interfaces. The deserializer 1124 enables the analog multiplication system 1102 to provide output data in formats compatible with various communication protocols and system interfaces.

The deserializer 1124 provides the processed data to the output memory 1112b for storage before the data is made available through the input/output interface 1106 as the output data 1106a. The memory controller 1114 coordinates the data transfer between the deserializer 1124 and the output memory 1112b, managing write operations, address generation, and data integrity verification. The output memory 1112b serves as a buffer for processed results, enabling the analog multiplication system 1102 to handle continuous data processing while providing stable output data availability for external systems.

The phase-locked loop (PLL) 1108 provides timing signals to various components including the deserializer 1116, the pulse width modulation generator 1118, the analog-to-digital converter 1122, and other timing-dependent elements within the analog multiplication system 1102 to maintain synchronization across the system operations. The timing coordination ensures that data transfer operations, PWM signal generation, multiplication operations, and ADC conversion occur in proper sequence with appropriate timing margins to prevent data corruption or processing errors, similar to how the reset switch 128 in FIG. 1 provides controlled timing for resetting the first output signal 124 before multiplication operations. The phase-locked loop (PLL) 1108 may provide multiple clock domains with different frequencies to optimize the performance of different system components while maintaining overall system synchronization through phase-locked timing relationships.

The analog multiplication system 1102 enables efficient implementation of multiply-accumulate operations commonly used in machine learning applications, digital signal processing algorithms, and other computational tasks that require large numbers of multiplication operations. The integration of memory storage with analog multiplication processing reduces the data movement overhead associated with conventional architectures that separate processing and memory functions. The analog multiplication system 1102 may support multiple precision requirements through configurable ADC resolution, variable PWM timing ranges, and scalable current source implementations within the multiplier circuit 1120, similar to how the modulated current element (MCE) 104 in FIG. 1 can be configured for different precision requirements.

The memory integration approach implemented by the analog multiplication system 1102 addresses the memory wall problem by bringing computation closer to data storage, reducing the latency and power consumption associated with data transfer between separate processing and memory units. The output lines from the memory unit 1110 that are operatively coupled to the current generation unit and signal generation unit of the multiplier circuit 1120 enable direct access to stored operands without requiring external memory interfaces or data buses that could introduce delays and power overhead, similar to how the current generation unit 108 and signal generation unit 112 in FIG. 1 directly receive the first control input 116 and second control input 118. This integration approach may provide significant performance advantages for applications that require frequent access to stored weight values, such as neural network inference operations where weight matrices are accessed repeatedly for different input data sets.

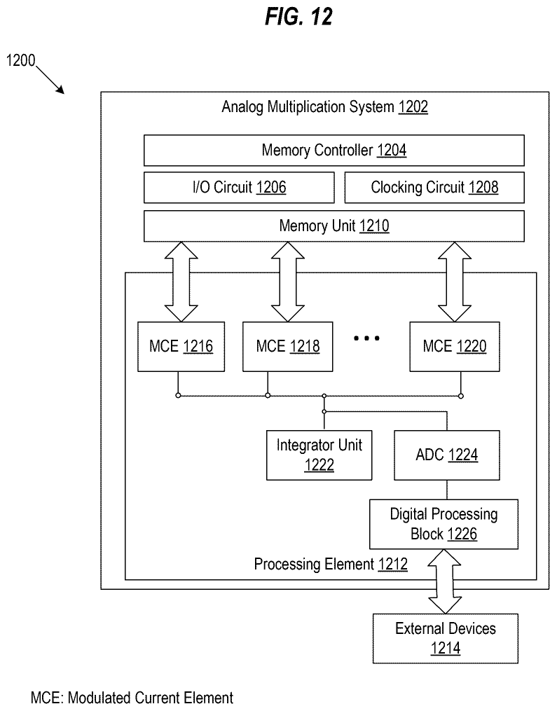

FIG. 12 is a block diagram that illustrates an analog multiplication system with multiple modulated current elements and processing components, in accordance with an embodiment of the disclosure. FIG. 12 is described in conjunction with elements from FIGS. 1-11. The block diagram 1200 shows an analog multiplication system 1202 that implements a distributed processing architecture with multiple processing elements for enhanced computational throughput and parallel operation capabilities. The analog multiplication system 1202 comprises a memory controller 1204, an I/O circuit 1206, a clocking circuit 1208, a memory unit 1210, and a processing element 1212, which are interconnected to provide efficient multiplication operations with integrated memory access and external device communication.

The memory controller 1204 manages data access and control operations for the memory unit 1210, implementing various memory management functions including address generation, data routing, access arbitration for multiple concurrent memory requests, and timing coordination for read and write operations. The memory controller 1204 may be implemented using dedicated memory controller circuits, embedded memory management units, or distributed control logic that coordinates memory access across multiple processing elements. The memory controller 1204 enables efficient data flow between the memory unit 1210 and the processing element 1212 by managing memory addressing, data transfer protocols, and access scheduling to optimize memory bandwidth utilization and minimize access latency.

The I/O circuit 1206 handles input and output operations for the analog multiplication system 1202, facilitating communication with external devices 1214. The I/O circuit 1206 may be implemented using various interface technologies including parallel data buses, serial communication protocols, high-speed differential signaling standards, or memory-mapped I/O architectures that enable efficient data transfer between the analog multiplication system 1202 and external systems. The external devices 1214 may include host processors, memory systems, other computational accelerators, or peripheral devices that provide input data for processing or receiving processed results from the analog multiplication system 1202. The I/O circuit 1206 enables the analog multiplication system 1202 to integrate within larger computational architectures while maintaining compatibility with various communication protocols and system interfaces.

The clocking circuit 1208 provides timing signals for synchronizing operations within the analog multiplication system 1202. The clocking circuit 1208 may be implemented using phase-locked loop (PLL) circuits, crystal oscillators, clock distribution networks, or timing generation circuits that provide stable clock signals with precise frequency control and low jitter characteristics. The clocking circuit 1208 generates timing references for coordinating memory access operations, data transfer between components, PWM signal generation within the processing element 1212, and ADC conversion timing to ensure synchronized operation across all components of the analog multiplication system 1202. The timing coordination provided by the clocking circuit 1208 may be distributed through buffered clock signals, differential clock pairs, or multiple clock domains with different frequencies to optimize the performance of different system components.

As shown in FIG. 12, the memory unit 1210 stores at least one of the digital operands and provides data to the processing element 1212 through bidirectional connections that enable data transfer between the memory unit 1210 and the processing element 1212. The memory unit 1210 may be implemented using various memory technologies including static random-access memory (SRAM) for high-speed access and low power consumption, dynamic random-access memory (DRAM) for high-density storage with refresh requirements, or non-volatile memory technologies such as flash memory, magnetoresistive RAM (MRAM), or phase-change memory (PCM) for persistent storage of weight values or configuration parameters. The memory unit 1210 is operatively coupled to the processing element 1212 through direct connections, shared bus structures, or dedicated data paths that enable efficient access to stored operands without requiring external memory interfaces.

The processing element 1212 includes multiple modulated current elements and additional processing components for performing multiplication operations using current-time domain processing techniques. The processing element 1212 comprises a modulated current element (MCE) 1216, a modulated current element (MCE) 1218, and a modulated current element (MCE) 1220, which are coupled to the memory unit 1210 for receiving digital operands and generating modulated current signals. Each of the modulated current elements 1216, 1218, and 1220 may be implemented using the current-time domain processing architectures described in FIGS. 1-8, including the binary-weighted current DAC circuits shown in FIGS. 2-4, the multiple current DAC configurations of FIGS. 5-6, the grouped current source implementation with differential biasing of FIG. 7, or the differential output generation approach of FIG. 8. The modulated current elements may include switching units controlled by PWM signals as described in FIGS. 2-3, and current generation units that selectively activate current sources based on digital operand values as shown in FIGS. 4-7. The multiple modulated current elements enable parallel processing of multiple multiplication operations simultaneously, increasing the computational throughput of the analog multiplication system 1202 compared to single-element implementations.

The processing element 1212 further includes an integrator unit 1222 that receives outputs from the modulated current elements 1216, 1218, and 1220. The integrator unit 1222 accumulates the current signals from the multiple modulated current elements to generate an analog output signal representing the combined result of multiple multiplication operations. The integrator unit 1222 may be implemented using any of the integration approaches described in FIGS. 1-8, including the common capacitor configuration shown in FIG. 1 connected between a shorted output of the switching unit and a common ground node, the parallel array of capacitors where each capacitor is between a common ground node and a respective switch with shorted outputs as described in the claims, the active integrator circuits with operational amplifiers for enhanced signal conditioning, or the differential capacitor pair configuration of FIG. 8 that enables complementary signal generation. The accumulation process enables the implementation of multiply-accumulate (MAC) operations where multiple multiplication results are combined to produce a single output value.

An analog-to-digital converter (ADC) 1224 is coupled to the integrator unit 1222 and converts the analog output signal into a digital representation suitable for further processing and output. The ADC 1224 may be implemented using various ADC architectures including successive approximation register (SAR) ADCs for moderate speed and precision requirements, sigma-delta ADCs for high precision applications with noise shaping capabilities, flash ADCs for high-speed conversion with parallel comparison, or pipeline ADCs for balanced speed and precision characteristics. The ADC 1224 enables the analog multiplication system 1202 to provide digital output results while performing multiplication operations in the analog domain, combining the efficiency advantages of analog processing with the compatibility requirements of digital systems.

A digital processing block 1226 is coupled to the ADC 1224 and processes the digital output from the ADC 1224 to provide additional signal conditioning, data formatting, or computational operations on the digitized multiplication results. The digital processing block 1226 may implement various digital signal processing functions including filtering, scaling, format conversion, error correction, or additional arithmetic operations that enhance the utility of the multiplication results for downstream applications. The digital processing block 1226 is also connected to the external devices 1214, enabling the analog multiplication system 1202 to provide processed results to external systems or receive additional data for processing through bidirectional communication interfaces.

The analog multiplication system 1202 operates by retrieving at least one of the digital operands from the memory unit 1210 and distributing them to the modulated current elements 1216, 1218, and 1220 within the processing element 1212. Each modulated current element processes its respective operands through current-time domain processing techniques, generating current pulses that are controlled by PWM signals and accumulated in the integrator unit 1222. The integrator unit 1222 combines the current contributions from the multiple modulated current elements to produce an analog signal representing the result of multiple multiplication operations. The ADC 1224 converts this analog signal to digital form, and the digital processing block 1226 performs additional processing before providing the results to the external devices 1214.

The memory controller 1204 coordinates data flow throughout the analog multiplication system 1202 by managing memory access operations, ensuring that digital operands are available to the processing element 1212 when needed, and coordinating the storage of intermediate or final results. The clocking circuit 1208 ensures synchronized operation of all components by providing timing references that coordinate memory access, data transfer, PWM signal generation, integration timing, and ADC conversion cycles. The I/O circuit 1206 manages communication with the external devices 1214, handling data input for processing operations and data output for processed results.

The analog multiplication system 1202 may be configured to store at least one of a first digital operand and a second digital operand in the memory unit 1210, with output lines from the memory unit 1210 operatively coupled to at least one of the current generation unit and the signal generation unit within each of the modulated current elements 1216, 1218, and 1220. This configuration enables in-memory computing functionality where multiplication operations are performed in close proximity to data storage, reducing data movement overhead and improving computational efficiency. The multiplier circuit functionality implemented by the processing element 1212 may be co-located on a semiconductor die or within a chip package that includes the memory unit 1210 or embedded within a physical layout of memory arrays to minimize interconnect delays and reduce power consumption through proximity.

The distributed processing architecture implemented by the analog multiplication system 1202 enables parallel processing of multiple multiplication operations, supporting applications that require high computational throughput such as neural network inference, matrix multiplication operations, or digital signal processing algorithms. The multiple modulated current elements within the processing element 1212 may operate simultaneously on different operand pairs, with the integrator unit 1222 accumulating the results to implement complex mathematical operations such as dot products, convolution operations, or multiply-accumulate sequences commonly used in machine learning applications.

The analog multiplication system 1202 provides advantages including increased computational throughput through parallel processing, efficient memory utilization through integrated storage and processing, reduced data movement overhead compared to conventional architectures that separate processing and memory functions, and scalable performance through the addition of multiple modulated current elements within the processing element 1212. The system architecture enables optimization of the trade-off between processing speed, power consumption, and area efficiency based on specific application requirements and performance targets.

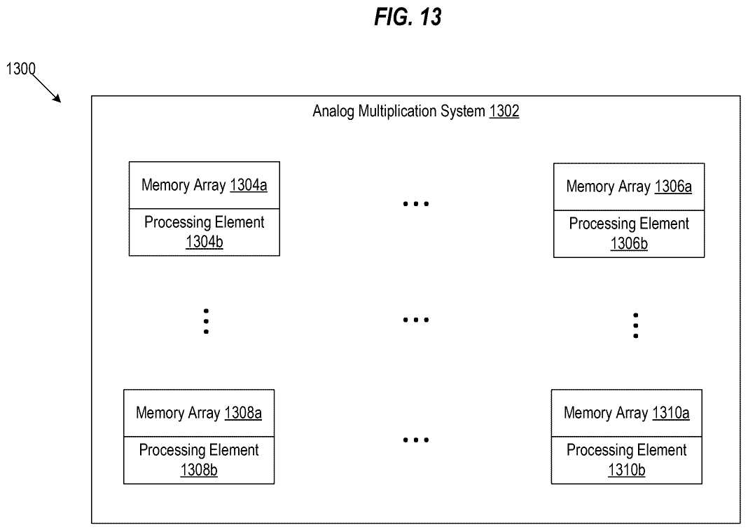

FIG. 13 is a block diagram that illustrates an analog multiplication system with distributed memory-processing element pairs, in accordance with an embodiment of the disclosure. FIG. 13 is described in conjunction with elements from FIGS. 1-12. The block diagram 1300 shows an analog multiplication system 1302 that implements a distributed architecture with multiple memory-processing pairs for enhanced computational throughput and scalable parallel operation capabilities. The analog multiplication system 1302 comprises multiple memory arrays and processing elements arranged in a distributed configuration that enables parallel processing of multiple multiplication operations across the system while maintaining efficient data access through co-located memory and processing resources.

The analog multiplication system 1302 comprises multiple memory arrays and processing elements arranged in computation units, specifically including a memory array 1304a paired with a processing element 1304b, a memory array 1306a paired with a processing element 1306b, a memory array 1308a paired with a processing element 1308b, and a memory array 1310a paired with a processing element 1310b. Each memory array is operatively coupled to its corresponding processing element, forming multiple computation units within the analog multiplication system 1302. The distributed arrangement enables independent operation of each computation unit while supporting coordinated processing across multiple units for complex computational tasks that require large-scale parallel multiplication operations.

The memory arrays 1304a, 1306a, 1308a, and 1310a store digital operands that are used in multiplication operations performed by their respective processing elements. Each memory array may be implemented using various memory technologies including static random-access memory (SRAM) for high-speed access and low power consumption, dynamic random-access memory (DRAM) for high-density storage with refresh requirements, or non-volatile memory technologies such as flash memory, magnetoresistive RAM (MRAM), or phase-change memory (PCM) for persistent storage of weight values or configuration parameters. The memory arrays may store different types of digital operands including weight matrices for neural network operations, filter coefficients for digital signal processing applications, or operand datasets for general-purpose multiplication operations.

The processing elements 1304b, 1306b, 1308b, and 1310b perform multiplication operations using current-time domain processing techniques based on the digital operands retrieved from their respective memory arrays. Each processing element may implement the multiplier circuit architectures described in FIGS. 1-8, including the modulated current element (MCE) configurations with current generation units, switching units, signal generation units, and integrator units as shown in FIGS. 2-6. The processing elements may utilize the binary-weighted current DAC circuits described in FIGS. 2-4, the multiple current DAC configurations with place value control shown in FIGS. 5-6, the grouped current source implementation with differential biasing of FIG. 7, or the differential output generation approach of FIG. 8. Each processing element may include multiple modulated current elements similar to the configuration shown in FIG. 12, enabling parallel processing of multiple multiplication operations within each computation unit.

The distributed arrangement of memory arrays and processing elements enables parallel processing of multiple multiplication operations across the analog multiplication system 1302. Each computation unit may operate independently on its stored operands while coordinating with other computation units for complex operations that require data sharing or result accumulation across multiple units. The parallel processing capability may provide significant computational throughput advantages for applications such as neural network inference where multiple weight matrices may be processed simultaneously, matrix multiplication operations where different matrix blocks may be computed in parallel, or digital signal processing applications where multiple filter operations may be performed concurrently.

The ellipsis notation in the diagram indicates that additional memory array and processing element pairs may be included in the analog multiplication system 1302 beyond those explicitly shown. The scalable architecture enables the system to be configured with varying numbers of computation units based on specific application requirements, performance targets, and available chip area. The modular design facilitates optimization of the trade-off between computational throughput, power consumption, and area efficiency by adjusting the number of computation units and their individual processing capabilities.

The architecture facilitates in-memory or near-memory computing by co-locating the processing elements with their associated memory arrays, reducing data movement and improving computational efficiency compared to conventional architectures that separate processing and memory functions. Each processing element may be co-located on a semiconductor die or within a chip package that includes its corresponding memory array or embedded within a physical layout of the memory array to minimize interconnect delays and reduce power consumption through proximity. Output lines from each memory array are operatively coupled to at least one of the current generation unit and the signal generation unit within the corresponding processing element, enabling direct access to stored operands without requiring external data transfer operations.

The distributed architecture may support various computational paradigms including single instruction, multiple data (SIMD) operations where the same multiplication operation is performed across multiple computation units with different operand sets, multiple instruction, multiple data (MIMD) operations where different computation units perform different types of multiplication operations simultaneously, or hybrid approaches that combine both paradigms based on the computational requirements of specific applications. The flexibility of the distributed architecture enables optimization for different types of workloads including neural network inference with static weight matrices, neural network training with dynamic weight updates, digital signal processing with streaming data, or general-purpose multiplication operations with varying operand characteristics.

The memory arrays within each computation unit may be configured to store different portions of larger operand matrices, enabling the distributed system to process large-scale matrix multiplication operations by distributing the computational load across multiple computation units. The processing elements may coordinate their operations through shared control signals, synchronized timing references, or inter-unit communication interfaces that enable result sharing and accumulation across multiple computation units. The distributed processing approach may provide significant performance advantages for applications that require processing of large datasets or complex mathematical operations that can be decomposed into multiple parallel multiplication tasks.

The analog multiplication system 1302 addresses the memory wall problem by eliminating the need for data transfer between separate memory and processing units within each computation unit, while scaling the solution across multiple computation units to handle large-scale computational tasks. The co-location of memory arrays and processing elements within each computation unit reduces the latency and power consumption associated with data movement, while the distributed architecture enables the system to scale computational throughput by adding additional computation units as needed. The approach may provide substantial improvements in operations per watt and operations per square millimeter compared to conventional digital architecture that relies on separate memory and processing units with external data transfer interfaces.

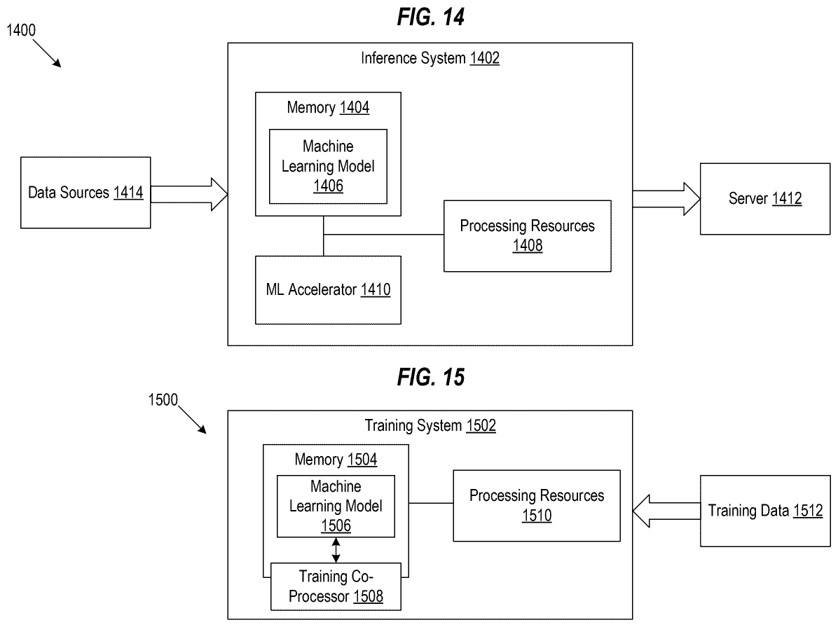

FIG. 14 is a block diagram that illustrates an inference system with ML accelerator for machine learning inference operations, in accordance with an embodiment of the disclosure. FIG. 14 is described in conjunction with elements from FIGS. 1-13. The block diagram 1400 shows an inference system 1402 that implements machine learning inference operations using current-time domain processing techniques for efficient multiply-accumulate operations. The inference system 1402 comprises a memory 1404, processing resources 1408, and an ML accelerator 1410, which are interconnected to provide inference capabilities for machine learning models while leveraging the computational efficiency advantages of analog multiplication operations.

The memory 1404 stores a machine learning model 1406 that contains the trained parameters, weight matrices, and configuration data required for performing inference operations on input data. The machine learning model 1406 may represent various types of neural network architecture including convolutional neural networks (CNNs) for image processing applications, recurrent neural networks (RNNs) for sequence processing tasks, transformer models for natural language processing, or fully connected networks for general classification and regression tasks.

Data sources 1414 provide input data to the inference system 1402 for processing through the machine learning model 1406. The data sources 1414 may include sensors, cameras, microphones, network interfaces, storage systems, or other data acquisition devices that generate input data requiring machine learning inference operations. The input data may represent images for computer vision applications, audio signals for speech recognition tasks, text data for natural language processing operations, or sensor measurements for predictive analytics and decision-making applications. The data sources 1414 may provide data in various formats including streaming data for real-time inference applications, batch data for high-throughput processing scenarios, or on-demand data for interactive inference operations.

The processing resources 1408 are operatively coupled to the memory 1404 and the ML accelerator 1410 to coordinate the flow of data between the data sources 1414, the memory 1404, and the ML accelerator 1410. The processing resources 1408 may include central processing units (CPUs), digital signal processors (DSPs), or dedicated control processors that manage data movement, coordinate inference operations, and handle system-level tasks such as scheduling, resource allocation, and result processing. The processing resources 1408 implement data flow management by retrieving input data from the data sources 1414, loading appropriate model parameters from the memory 1404, coordinating inference operations through the ML accelerator 1410, and managing the output of processed results.

The ML accelerator 1410 is configured to perform inference operations using the machine learning model 1406 stored in the memory 1404. The ML accelerator 1410 may implement the current-time domain processing techniques described in FIGS. 1-13, including the multiplier circuit architectures with modulated current elements, current generation units, switching units, and integrator units that enable efficient multiply-accumulate operations commonly required in neural network inference. The ML accelerator 1410 may comprise multiple processing elements similar to those described in FIGS. 12-13, with distributed memory arrays and processing elements that enable parallel processing of multiple multiplication operations simultaneously. The ML accelerator 1410 utilizes current-time domain processing to perform the matrix multiplication operations, convolution operations, and other computational tasks required for neural network inference with improved energy efficiency compared to conventional digital processing approaches.

As shown in FIG. 14, the inference system 1402 outputs processed results to a server 1412. The server 1412 receives the inference results from the inference system 1402 for further processing, storage, or distribution to downstream applications or users. The server 1412 may implement various functions including result aggregation, post-processing operations, data formatting for specific applications, or communication with external systems that utilize the inference results. The server 1412 may be implemented as a local server for edge computing applications, a cloud-based server for distributed inference services, or a hybrid system that combines local and remote processing capabilities based on application requirements and network connectivity.

The inference system 1402 may be optimized for various deployment scenarios including edge computing applications, datacenter applications, or mobile applications. The current-time domain processing implemented by the ML accelerator 1410 may provide advantages for inference operations by reducing the power consumption associated with multiply-accumulate operations while maintaining the computational accuracy required for machine learning applications. The analog multiplication operations may enable higher computational density and improved energy efficiency compared to conventional digital implementations, particularly for applications that require processing of large neural networks with millions or billions of parameters.

FIG. 15 is a block diagram that illustrates a training system with training co-processor for machine learning model training operations, in accordance with an embodiment of the disclosure. FIG. 15 is described in conjunction with elements from FIGS. 1-14. The block diagram 1500 shows a training system 1502 that implements machine learning training operations using current-time domain processing techniques for efficient computation of gradients, weight updates, and backpropagation operations. The training system 1502 comprises a memory 1504, processing resources 1510, and a training co-processor 1508, which are interconnected to provide high-performance training capabilities for machine learning models while leveraging the computational efficiency advantages of analog multiplication operations for the intensive computational requirements of training algorithms.

The memory 1504 stores a machine learning model 1506 that contains the model parameters, weight matrices, gradient information, and configuration data that are dynamically updated during the training process. The memory 1504 may be implemented using various memory technologies including static random-access memory (SRAM) for high-speed access to frequently updated parameters during training iterations, dynamic random-access memory (DRAM) for high-capacity storage of large model weights and gradient information, or high-bandwidth memory (HBM) for applications requiring extremely high memory bandwidth to support intensive training operations. The machine learning model 1506 undergoes continuous updates during training as the model parameters are adjusted based on training data and gradient computations to improve the model's performance on the target task.

Training data 1512 is provided to the training system 1502 to drive the learning process for the machine learning model 1506. The training data 1512 may include labeled datasets for supervised learning applications, unlabeled data for unsupervised learning tasks, or combinations of labeled and unlabeled data for semi-supervised learning approaches. The training data 1512 may represent various data types including images with associated labels for computer vision tasks, text corpora for natural language processing applications, audio recordings with transcriptions for speech recognition systems, or sensor data with target outputs for predictive modeling applications. The training data 1512 may be provided in batches for batch gradient descent training, individual samples for stochastic gradient descent, or mini-batches for mini-batch gradient descent approaches that balance computational efficiency with convergence stability.

The processing resources 1510 are operatively coupled to the memory 1504 and the training co-processor 1508 to manage the flow of training data 1512 and coordinate updates to the machine learning model 1506 during the training process. The processing resources 1510 may include central processing units (CPUs), graphics processing units (GPUs), or dedicated control processors that handle data preprocessing, batch management, learning rate scheduling, convergence monitoring, and coordination of training operations across multiple processing elements. The processing resources 1510 implement training workflow management by loading training data batches, coordinating forward and backward propagation operations, managing gradient computations and weight updates, and monitoring training progress through loss function evaluation and validation metrics.

The training co-processor 1508 is configured to perform training operations on the machine learning model 1506 using the training data 1512. The training co-processor 1508 implements the computational operations required for machine learning training including forward propagation through the neural network, backpropagation for gradient computation, and weight update operations based on computed gradients. The training co-processor 1508 may utilize current-time domain processing techniques described in FIGS. 1-13 to efficiently perform multiply-accumulate operations required during backpropagation and weight updates. The training co-processor 1508 may implement the multiplier circuit architectures with modulated current elements, current generation units, switching units, and integrator units that enable efficient computation of gradients and parameter updates with improved energy efficiency compared to conventional digital training approaches.

The training co-processor 1508 may comprise multiple processing elements similar to those described in FIGS. 12-13, with distributed memory arrays and processing elements that enable parallel processing of multiple gradient computations and weight updates simultaneously. The current-time domain processing approach may provide significant computational advantages for training operations by enabling efficient computation of the matrix multiplication operations required for gradient backpropagation, the element-wise operations needed for weight updates, and the accumulation operations required for batch processing. The analog multiplication operations may enable higher computational throughput and improved energy efficiency compared to conventional digital implementations, particularly for training large neural networks that require extensive computational resources.

The memory 1504 provides access to the machine learning model 1506 for the training co-processor 1508, enabling dynamic updates to model parameters based on gradient computations and optimization algorithms. The training process involves iterative updates to the machine learning model 1506 where the training co-processor 1508 computes gradients based on the training data 1512, applies optimization algorithms such as stochastic gradient descent, Adam, or other optimization methods to determine parameter updates, and modifies the stored model parameters in the memory 1504. The iterative training process continues until convergence criteria are met, such as achieving target accuracy levels, reaching maximum training iterations, or satisfying early stopping conditions based on validation performance.

The training system 1502 iteratively updates the machine learning model 1506 based on the training data 1512 through a systematic training process that may include forward propagation to compute model outputs, loss function evaluation to measure prediction errors, backward propagation to compute gradients with respect to model parameters, and parameter updates based on optimization algorithms. The training co-processor 1508 coordinates these operations using current-time domain processing techniques that may provide computational advantages for the intensive multiply-accumulate operations required throughout the training process. The analog multiplication operations may enable more efficient computation of gradient calculations, weight updates, and accumulation operations compared to conventional digital training implementations.

The training system 1502 may support various training paradigms including supervised learning with labeled training data, unsupervised learning with unlabeled data for tasks such as autoencoders or generative models, reinforcement learning with reward signals for decision-making applications, or transfer learning where pre-trained models are fine-tuned for specific tasks.

Reference throughout this specification to “an example” means that a particular feature, structure, or characteristic described in connection with the example is included in at least one embodiment of the present invention. Thus, appearances of the phrase “in an example” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on its presentation in a common group without indications to the contrary. In addition, various embodiments and examples of the present invention may be referred to herein along with alternatives for the various components thereof. It is understood that such embodiments, examples, and alternatives are not to be construed as de facto equivalents of one another but are to be considered as separate and autonomous representations of the present invention.

Although the foregoing has been described in some detail for purposes of clarity, it will be apparent that certain changes and modifications may be made without departing from the principles thereof. It should be noted that there are many alternative ways of implementing both the processes and apparatuses described herein. Accordingly, the present embodiments are to be considered illustrative and not restrictive, and the invention is not to be limited to the details given herein but may be modified within the scope and equivalents of the appended claims.

Those having skill in the art will appreciate that many changes may be made to the details of the above-described embodiments without departing from the underlying principles of the invention. The scope of the present invention should, therefore, be determined only by the following claims.

What is claimed is:

1. A multiplier circuit, comprising:
a signal generation unit configured to generate at least one control signal based on a first control input;
a current generation unit configured to generate a plurality of current pulses based on a second control input,
wherein each of the first control input and the second control input represents at least one component of a first digital operand or a second digital operand;
a switching unit operatively coupled to the current generation unit; and
an integrator unit coupled to an output node of the switching unit,
wherein the switching unit is configured to selectively control, based on the at least one control signal, a flow of the plurality of current pulses towards the integrator unit to generate a first output signal at the integrator unit, and
the first output signal represents a result of a multiplication operation between the first digital operand and the second digital operand.

2. The multiplier circuit according to claim 1, wherein the current generation unit comprises a current Digital-to-Analog (DAC) circuit,
the current DAC circuit comprises a plurality of binary-weighted current sources and a plurality of internal switches respectively coupled to the plurality of binary-weighted current sources, and
an application of the second control input to the plurality of internal switches selectively activates the plurality of binary-weighted current sources to generate the plurality of current pulses.

3. The multiplier circuit according to claim 2, wherein the first digital operand includes a first digit component and a unit place value component corresponding to the first digit component, and
the second digital operand includes a second digit component and a unit place value component corresponding to the second digit component.

4. The multiplier circuit according to claim 3, wherein:
the switching unit includes a switch coupled to a shorted node of the current DAC circuit,
the plurality of current pulses are combined at the shorted node of the current DAC circuit to generate an output current,
the at least one component for the first control input includes the first digit component,
the at least one control signal includes a Pulse Width Modulated (PWM) signal with a pulse duration that corresponds to a value of the first digit component, and
the switching unit is configured to control the flow of the output current over the pulse duration to generate the first output signal.

5. The multiplier circuit according to claim 3, wherein:
the switching unit includes a plurality of switches coupled to the plurality of internal switches of the current DAC circuit,
the at least one component for the first control input includes the first digit component,
the at least one control signal includes a plurality of Pulse Width Modulated (PWM) signals,
each PWM signal of the plurality of PWM signals is associated with a pulse duration that corresponds to a value of the first digit component, and
the switching unit is configured to control the flow of the plurality of current pulses current over the pulse duration to generate the first output signal.

6. The multiplier circuit according to claim 3, wherein:
the at least one component for the second control input includes the second digit component,
the second control input includes a set of bit values that represent the second digit component, and
the set of bit values acts as a respective set of control signals for the plurality of internal switches.

7. The multiplier circuit according to claim 1, wherein the first digital operand includes a first digit component and a unit place value component corresponding to the first digit component, and
the second digital operand includes a second digit component as a set of bit values and a second place value component as a set of place values corresponding to the set of bit values.

8. The multiplier circuit according to claim 7, wherein the current generation unit comprises a plurality of current Digital-to-Analog (DAC) circuits, and
each current DAC circuit of the plurality of current DAC circuits comprises a current source and an internal switch coupled to the current source.

9. The multiplier circuit according to claim 8, wherein:
the switching unit includes a plurality of switches,
each switch of the plurality of switches is coupled to the internal switch of a respective current DAC circuit of the plurality of current DAC circuits,
the at least one component for the first control input includes the first digit component and the second place value component,
the at least one control signal includes a plurality of Pulse Width Modulated (PWM) signals,
each PWM signal of the plurality of PWM signals is associated with a respective pulse duration that is proportional to a product of a value of the first digit component and a respective place value of the set of place values, and
the switching unit is configured to control the flow of each current pulse of the plurality of current pulses over the respective pulse duration to generate the first output signal.

10. The multiplier circuit according to claim 8, wherein
the at least one component for the second control input includes the second digit component,
the second control input includes the set of bit values that represent the second digit component,
each binary value of the set of binary values acts as a respective control signal for the internal switch of a respective current DAC circuit of the plurality of current DAC circuits, and
an application of each binary value of the set of bit values to the internal switch of the respective current DAC circuit selectively activates the current source in the respective current DAC circuit of the plurality of current DAC circuits to generate a respective current pulse of the plurality of current pulses.

11. The multiplier circuit according to claim 1, wherein the first digital operand includes a first digit component as a set of bit values and a second place value component as a set of place values corresponding to the set of bit values, and
the second digital operand includes a second digit component and a unit place value component corresponding to the second digit component.

12. The multiplier circuit according to claim 11, wherein the switching unit includes a set of switches corresponding to the set of bit values, and the at least one component for the first control input includes the first digit component.

13. The multiplier circuit according to claim 12, wherein the current generation unit comprises a plurality of current Digital-to-Analog (DAC) circuits in a specific configuration,
the specific configuration includes a specific set of current DAC circuits of the plurality of current DAC circuits for each switch of the set of switches, and
a number of current DAC circuits in the specific set of current DAC circuits corresponds to a respective place value of the set of place values.

14. The multiplier circuit according to claim 13, wherein each current DAC circuit of the plurality of current DAC circuits comprises a plurality of binary-weighted current sources and a plurality of internal switches respectively coupled to the plurality of binary-weighted current sources,
the at least one component for the second control input includes the second digit component,
the second control input includes a set of bit values representing the second digit component, and
an application of the set of bit values to the plurality of binary-weighted current sources selectively activates the plurality of binary-weighted current sources in each current DAC circuit of the plurality of current DAC circuits to generate a respective current pulse of the plurality of current pulses.

15. The multiplier circuit according to claim 14, wherein:
each switch of the set of switches is coupled to a shorted output of the specific set of current DAC circuits,
the at least one component for the first control input includes the first digit component,
the at least one control signal includes a plurality of Pulse Width Modulated (PWM) signals,
each PWM signal of the plurality of PWM signals is associated with a respective pulse duration that is proportional to a respective bit value of the set of bit values, and
the switching unit is configured to control the flow of each current pulse of the plurality of current pulses over the respective pulse duration to generate the first output signal.

16. The multiplier circuit according to claim 1, wherein the at least one control signal is a Pulse Width Modulated (PWM) signal and the signal generation unit includes a Digital-to-Time (DTC) converter.

17. The multiplier circuit according to claim 1, wherein:
the first output signal is a voltage signal that is generated based on a charge accumulation on the integrator unit over a pulse duration of the at least one control signal, and
the charge accumulation is caused by the controlled flow of the plurality of current pulses towards the integrator unit.

18. The multiplier circuit according to claim 1, wherein the current generation unit includes a current Digital-to-Analog Converter (DAC) circuit comprising at least one current source,
the at least one current source comprises a set of transistors in a parallel configuration, and
each transistor of the set of transistors includes a gate terminal coupled to a common bias voltage.

19. The multiplier circuit according to claim 1, wherein the current generation unit includes a current Digital-to-Analog Converter (DAC) circuit,
the current DAC circuit comprises a plurality of current sources in a plurality of groups,
each current source of the plurality of current sources is a binary-weighted current source that corresponds to a respective place value of a respective bit of one of the first digital operand or the second digital operand,
each group of the plurality of groups includes at least one current source of the plurality of current sources,
the at least one current source in each group of the plurality of groups includes a specific transistor-based circuit that is biased with a different bias voltage, and
the different bias voltage for each group of the plurality of groups is such that a current output of each current source of the at least one current source in a respective group of the plurality of groups is proportional to the respective place value corresponding to a respective current source of the plurality of current sources.

20. The multiplier circuit according to claim 1, wherein the integrator unit comprises an integrator circuit with at least one active circuit component.

21. The multiplier circuit according to claim 1, wherein the integrator unit comprises a parallel array of capacitors,
each capacitor of the parallel array of capacitors is between a common ground node and a respective switch of a set of switches of the switching unit, and
an output across each capacitor of the parallel array of capacitors is shorted.

22. The multiplier circuit according to claim 1, wherein the integrator unit comprises a common capacitor connected between a shorted output of the switching unit and a common ground node.

23. The multiplier circuit according to claim 1, wherein:
the current generation unit comprises a plurality of current sources and a plurality of internal switches respectively coupled to the plurality of current sources,
the switching unit comprises a plurality of switch pairs,
an input to each switch pair of the plurality of switch pairs is coupled to a respective internal switch of the plurality of internal switches,
the at least one control signal includes a respective pair of complementary signals for each switch pair of the plurality of switch pairs,
each switch pair of the plurality of switch pairs comprises a first switch for a first signal of the respective pair of complementary signals and a second switch for a second signal of the respective pair of complementary signals,
the integrator unit comprises a pair of capacitors,
outputs of the first switch from each switch pair of the plurality of switch pairs is shorted and coupled to a first capacitor of the pair of capacitors,
outputs of the second switch from each switch pair of the plurality of switch pairs is shorted and coupled to a second capacitor of the pair of capacitors,
an application of the respective pair of complementary signals to each switch pair of the plurality of switch pairs selectively controls the flow of the plurality of current pulses towards the pair of capacitors to generate the first output signal at the first capacitor and a second output signal at the second capacitor, and
the second output signal is different from the first output signal.

24. The multiplier circuit according to claim 23, further comprising a signal processing unit configured to generate a third output signal based on the first output signal and the second output signal, wherein the third output signal represents the result of the multiplication operation between the first digital operand and the second digital operand.

25. The multiplier circuit according to claim 1, further comprising a memory array configured to store the second digital operand, and output lines from the memory array are operatively coupled to the current generation unit.

26. The multiplier circuit according to claim 25, wherein the multiplier circuit is:
co-located on a semiconductor die or within a chip package that includes the memory array, or
embedded within a physical layout of the memory array.

27. The multiplier circuit according to claim 1, further comprising an analog-to-digital converter configured to convert the first output signal to a digital output representing the result in a digital form.

28. The multiplier circuit according to claim 1, further comprising a reset switch operatively coupled to the integrator unit, wherein the reset switch is configured to reset the first output signal to an initial value before the multiplication operation.

29. A method for performing a multiplication operation, comprising:
generating at least one control signal based on a first control input;
generating an output current through a current generation unit based on a second control input, wherein each of the first control input and the second control input represent at least one component of a first digital operand or a second digital operand; and
selectively controlling, based on the at least one control signal, a flow of the output current towards an integrator unit to generate a first output signal at the integrator unit,
wherein the first output signal represents a result of the multiplication operation between the first digital operand and the second digital operand.

30. An analog multiplication system, comprising:
a memory unit configured to store at least one of a first digital operand and a second digital operand; and
a multiplier circuit comprising:
a signal generation unit configured to generate at least one control signal based on a first control input;
a current generation unit configured to generate a plurality of current pulses based on a second control input,
wherein output lines from the memory unit are operatively coupled to at least one of the current generation unit and the signal generator unit, and
each of the first control input and the second control input represents at least one component of the first digital operand or the second digital operand;
a switching unit operatively coupled to the current generation unit; and
an integrator unit coupled to an output node of the switching unit,
wherein the switching unit is configured to selectively control, based on the at least one control signal, a flow of the plurality of current pulses towards the integrator unit to generate a first output signal at the integrator unit, and
the first output signal represents a result of a multiplication operation between the first digital operand and the second digital operand.
